(19) United States
(12) Patent Application Publication
(10) Pub. No.: US 2026/0153543 A1
(43) Pub. Date: Jun. 4, 2026

(54) PHASE CHARACTERISTIC MEASUREMENT APPARATUS, SIGNAL GENERATOR AND SIGNAL ANALYZER HAVING SAME, AND PHASE CHARACTERISTIC MEASUREMENT METHOD

(71) Applicant: ANRITSU CORPORATION, Kanagawa (JP)

(72) Inventors: Hiroto FUJISAKI, Kanagawa (JP); Takashi MORI, Kanagawa (JP)

(21) Appl. No.: 19/403,086

(22) Filed: Nov. 27, 2025

(30) Foreign Application Priority Data
Dec. 4, 2024 (JP) 2024-211592

(51) Int. Cl. G01R 25/00; G01R 19/00; G01R 23/14; G01R 25/04

(52) U.S. Cl. CPC G01R 25/005; G01R 19/0084; G01R 23/14; G01R 25/04

(57) ABSTRACT

A first detector that receives and detects 3-tone signals of three patterns of a first 3-tone signal obtained by combining three waves of angular frequencies ω₁, ω₂, and ω₃ (here, ω₂−ω₁=ω₃−ω₂=Δω is established), a second 3-tone signal in which each tone has a phase offset, and a third 3-tone signal having a phase offset different from the phase offset of the second 3-tone signal, a BPF that allows only a beat component of an angular frequency difference Δω between adjacent waves of the 3-tone signals among signals output from the first detector to pass, a second detector that detects power of the beat component that has passed through the BPF, a voltmeter that measures a voltage of a signal output from the second detector, and a phase calculator that calculates a phase based on the measured voltage values of the three patterns.

### TECHNICAL FIELD

The present invention relates to a phase characteristic measurement apparatus, a signal generator and a signal analyzer having the same, and a phase characteristic measurement method.

### BACKGROUND ART

In order to improve a transmission rate in wireless communication, a communication method using wideband modulated signals in a millimeter wave band, a submillimeter wave band, or a terahertz wave band having a higher carrier frequency than in the related art is being studied. Hereinafter, the millimeter wave band, the submillimeter wave band, the terahertz wave band, and the like are collectively referred to as a high-frequency band, and a signal in the high-frequency band is collectively referred to as a high-frequency signal.

In general, in a high frequency and wide bandwidth, a frequency characteristic of a phase of a frequency conversion unit (up-converter or down-converter) of a high-frequency band signal generator or a high-frequency band signal analyzer cannot be neglected. Therefore, it is important to calibrate the phase characteristic of the frequency conversion unit. Furthermore, in a multi-level quadrature amplitude modulation method that has high spectral efficiency, a small phase error can cause degradation of a transmission characteristic, so accurate calibration of the phase characteristic is required.

### RELATED ART DOCUMENT

### Patent Document

[Patent Document 1] Japanese Patent No. 5572590
[Patent Document 2] Japanese Patent No. 6839226

### DISCLOSURE OF THE INVENTION

### Problem that the Invention is to Solve

The related art disclosed in Patent Document 1 is a technology of measuring a frequency characteristic of a phase (simply referred to as a phase characteristic) by inputting two tone signals in a high-frequency band such as millimeter waves to an envelope detector (simply referred to as a detector), measuring a beat between tones by the detector, and detecting a phase difference between the tones. However, in this method, it is necessary to obtain an initial phase of the beat between the tone signals. In order to obtain the initial phase, it is necessary to trigger an analog to digital converter (A/D converter) that acquires a time waveform of a detector output signal and synchronize the triggered A/D converter with a tone signal generator. There is a problem that expensive components are required in order to perform such a high-speed trigger operation.

In order to solve the above-described problem, there is a method of acquiring time waveforms of three tone signals in a high-frequency band, such as millimeter waves, and calculating a phase characteristic. By using the three tone signals, it is possible to measure the phase characteristic even in a case where the A/D converter is not triggered and the initial phase is unknown. Examples of the measurement using the 3-tone signal include an electro-optic sampling method (for example, see Patent Document 2) and a method of down-converting a high-frequency signal such as millimeter waves. In particular, by using the electro-optic sampling method, the phase characteristic of a very high frequency can be accurately obtained. However, on the other hand, there is a problem that an optical system such as a femtosecond laser is required, making the apparatus large in scale. In the method of down-conversion, there is a problem that a local signal in a high-frequency band, such as millimeter waves, is required, making the apparatus large in scale.

The present invention has been made in order to solve the above-described problems, and an object of the present invention is to provide a phase characteristic measurement apparatus that can realize a phase measurement at a relatively low cost without increasing the scale of the apparatus used for the phase measurement, a signal generator and a signal analyzer having the same, and a phase characteristic measurement method.

### Means for Solving the Problem

In order to achieve the above object, a phase characteristic measurement apparatus according to the present invention includes a first detector (11) that receives and detects a first 3-tone signal obtained by combining three waves e₁, e₂, and e₃ represented by Equation (1) and a second 3-tone signal obtained by combining three waves e₁, e₂, and e₃ represented by Equation (2) as a signal for phase measurements, respectively, a band-pass filter (12) that, among signals output from the first detector, allows a frequency component of an angular frequency difference Δω between waves with adjacent frequencies of each of the signals for phase measurements to pass and blocks a frequency component twice the angular frequency difference Δω and a direct current component, a second detector (13) that detects a signal that has passed through the band-pass filter, a voltmeter (14) that measures a voltage of a signal output from the second detector, and a phase calculator (15) that calculates a phase φ₂″ represented by Equation (3).

$$\begin{matrix}[ Equation 1 ] & \\ {e}_{i} = cos ( {w}_{i} t + {ϕ}_{i} ) , i = 1 , 2 , 3 & ( 1 )\end{matrix}$$

$$\begin{matrix}[ Equation 2 ] & \\ {e}_{i} = cos ( {w}_{i} t + {ϕ}_{i} + {α}_{i} ) , i = 1 , 2 , 3 & ( 2 )\end{matrix}$$

$$\begin{matrix}[ Equation 3 ] & \\ {ϕ}_{2}^{″} = \{ \begin{matrix}\frac{2}{Δ {ω}^{2}} {tan}^{- 1} ( \frac{\begin{matrix}\sqrt{\frac{{E}_{beat} ( {ϕ}_{α} )}{{E}_{beat} ( 0 )}} + \\ cos ( \frac{{ϕ}_{α}}{2} )\end{matrix}}{sin ( \frac{{ϕ}_{α}}{2} )} ) , & π - {ϕ}_{α} \leq {ϕ}_{3} - 2 {ϕ}_{2} + {ϕ}_{1} \leq π \\ \frac{2}{Δ {ω}^{2}} {tan}^{- 1} ( \frac{\begin{matrix}- \sqrt{\frac{{E}_{beat} ( {ϕ}_{α} )}{{E}_{beat} ( 0 )}} + \\ cos ( \frac{{ϕ}_{α}}{2} )\end{matrix}}{sin ( \frac{{ϕ}_{α}}{2} )} ) , & - π \leq {ϕ}_{3} - 2 {ϕ}_{2} + {ϕ}_{1} \leq π - {ϕ}_{α}\end{matrix} & ( 3 )\end{matrix}$$

(In Equations (1), (2), and (3), ωᵢ represent angular frequencies, φᵢ represent phases, t represents a time, and ω₂−ω₁=ω₃−ω₂=Δω is established, αᵢ are phase offsets of the second 3-tone signal, and φ_{α}=α₃−2α₂+α₁ is established when a second-order difference of αᵢ is represented by φ_{A}, E_{beat}(φ_{α}) represents a value that is obtained from a voltage value measured by the voltmeter and that is proportional to power of the signal that has passed through the band-pass filter, in a case where the second 3-tone signal in which the second-order difference of αᵢ is set to φ_{α} is detected by the first detector, and E_{beat}(0) represents a value that is obtained from a voltage value measured by the voltmeter and that is proportional to power of the signal that has passed through the band-pass filter, in a case where the first 3-tone signal is detected by the first detector.)

With this configuration, power of a beat component of the angular frequency Δω is measured by the second detector for the 3-tone signals of two patterns of the first 3-tone signal represented by Equation (1) in which all 3 tones have the equal amplitude, and the second 3-tone signal represented by Equation (2), which has the equal amplitude as the first 3-tone signal and a phase offset with respect to the first 3-tone signal, and as a result, a phase relationship (second-order differential value) of the 3 tones represented by Equation (3) can be calculated. Accordingly, it is possible to provide a phase characteristic measurement apparatus that can realize a phase measurement at a relatively low cost without increasing the scale of the apparatus by using a detector and a voltmeter that do not require a high-speed trigger operation. In this phase characteristic measurement apparatus, a phase can be measured by two times of measurements.

Further, in order to achieve the above object, a phase characteristic measurement apparatus according to the present invention includes a first detector (11) that receives and detects a first 3-tone signal obtained by combining three waves e₁, e₂, and e₃ represented by Equation (4), a second 3-tone signal obtained by combining three waves e₁, e₂, and e₃ represented by Equation (5), and a third 3-tone signal obtained by combining three waves e₁, e₂, and e₃ represented by Equation (6) as a signal for phase measurements, respectively, a second detector (13) that detects a signal output from the first detector, a voltmeter (14) that measures a voltage of a signal output from the second detector, and a phase calculator (15) that calculates a phase φ₂″ represented by Equation (7) or Equation (11).

$$\begin{matrix}[ Equation 4 ] & \\ {e}_{i} = {a}_{i} cos ( {w}_{i} t + {ϕ}_{i} ) , i = 1 , 2 , 3 & ( 4 )\end{matrix}$$

$$\begin{matrix}[ Equation 5 ] & \\ {e}_{i} = {a}_{i} cos ( {w}_{i} t + {ϕ}_{i} + {α}_{1 i} ) , i = 1 , 2 , 3 & ( 5 )\end{matrix}$$

$$\begin{matrix}[ Equation 6 ] & \\ {e}_{i} = {a}_{i} cos ( {w}_{i} t + {ϕ}_{i} + {α}_{2 i} ) , i = 1 , 2 , 3 & ( 6 )\end{matrix}$$

$$\begin{matrix}[ Equation 7 ] & \\ \text{?} = \frac{1}{Δ {ω}^{\text{?}}} ( {tan}^{- 1} ( \frac{cos ( Δ {ϕ}_{\text{?}} )}{cos ( Δ {ϕ}_{\text{?}} ) + sin ( Δ {ϕ}_{\text{?}} )} ( \frac{{E}_{beat} ( 0 ) - 2 {E}_{beat} ( {ϕ}_{\text{?}} ) + {E}_{beat} ( {ϕ}_{\text{?}} )}{{E}_{beat} ( 0 ) - {E}_{beat} ( {ϕ}_{\text{?}} )} - \frac{sin ( Δ {ϕ}_{\text{?}} )}{cos ( Δ {ϕ}_{\text{?}} )} ) ) - Δ {ϕ}_{\text{?}} ) & ( 7 )\end{matrix}$$

$$\begin{matrix}[ Equation 11 ] & \\ {ϕ}_{2}^{″} = \frac{1}{Δ {ω}^{2}} ( atan 2 ( \frac{cos ( Δ {ϕ}_{α 2} )}{cos ( Δ {ϕ}_{α 1} ) + sin ( Δ {ϕ}_{α 2} )} ( cos ( Δ {ϕ}_{α 2} ) ( {E}_{beat} ( 0 ) - 2 {E}_{beat} ( {ϕ}_{α 1} ) + {E}_{beat} ( {ϕ}_{α 2} ) ) - sin ( Δ {ϕ}_{α 1} ) ( {E}_{beat} ( 0 ) - {E}_{beat} ( {ϕ}_{α 2} ) ) ) , cos ( Δ {ϕ}_{α 2} ) ( {E}_{beat} ( 0 ) - {E}_{beat} ( {ϕ}_{α 2} ) ) ) - Δ {ϕ}_{α 2} ) & ( 11 )\end{matrix}$$

$$\text{?} \text{indicates text missing or illegible when filed}$$

(In Equations (4), (5), (6), (7), and (11), αᵢ represent amplitudes, ωᵢ represent angular frequencies, φᵢ represent phases, t represents a time, and ω₂−ω₁=ω₃−ω₂=Δω is established, α₁ᵢ are phase offsets of the second 3-tone signal, and φ_{α1}=α₁₃−2α₁₂+α₁₁ is established when a second-order difference of α₁ᵢ is represented by φ_{α1}, α₂ᵢ are phase offsets of the third 3-tone signal, and φ_{α2}=α₂₃−2α₂₂+α₂₁ is established when a second-order difference of α₂₁ is represented by φ_{α2}, φ_{α1}=π/2+Δφ_{α1}+Δφ_{α2}, and φ_{α2}=π+2Δφ_{α2} are established, E_{beat}(0) represents a value that is obtained from a voltage value measured by the voltmeter and that is proportional to power of the signal output from the first detector, in a case where the first 3-tone signal is detected by the first detector, E_{beat}(φ_{α1}) represents a value that is obtained from a voltage value measured by the voltmeter and that is proportional to power of the signal output from the first detector, in a case where the second 3-tone signal in which the second-order difference of α₁ᵢ is set to φ_{α1} is detected by the first detector, and E_{beat}(φ_{α2}) represents a value that is obtained from a voltage value measured by the voltmeter and that is proportional to power of the signal output from the first detector, in a case where the third 3-tone signal in which the second-order difference of α₂₁ is set to φ_{α2} is detected by the first detector.)

With this configuration, power of a beat component of the angular frequency Δω or a value obtained by adding an offset to the power is measured by the second detector for the 3-tone signals of three patterns having different phase offsets represented by Equations (4), (5), and (6), and as a result, a phase relationship (second-order differential value) of the 3 tones represented by Equation (7) or Equation (11) can be calculated even in a case where the amplitudes of the 3 tones are unknown and are unequal amplitudes. By using the a tan 2 function in Equation (11), a phase measurement range becomes wider than in a case where the tan⁻¹ function in Equation (7) is used. Accordingly, it is possible to provide a phase characteristic measurement apparatus that can realize a phase measurement at a relatively low cost without increasing the scale of the apparatus by using a detector and a voltmeter that do not require a high-speed trigger operation. In this configuration, the phase calculator has a characteristic of not being affected by a direct current offset during a voltage measurement and a band-pass filter (BPF) for extracting an angular frequency Oo component of a beat is not necessary. However, it is desirable to use the BPF in order to improve signal-to-noise ratio (S/N).

In order to achieve the above object, a phase characteristic measurement apparatus according to the present invention includes a first detector (11) that receives and detects a first 3-tone signal obtained by combining three waves e₁, e₂, and e₃ represented by Equation (12), a second 3-tone signal obtained by combining three waves e₁, e₂, and e₃ represented by Equation (13), a third 3-tone signal obtained by combining three waves e₁, e₂, and e₃ represented by Equation (14), and a fourth 3-tone signal obtained by combining three waves e₁, e₂, and e₃ represented by Equation (15) as a signal for phase measurements, respectively, a second detector (13) that detects a signal output from the first detector, a voltmeter (14) that measures a voltage of a signal output from the second detector, and a phase calculator (15) that calculates a phase φ₂″ represented by Equation (16) or Equation (21).

$$\begin{matrix}[ Equation 12 ] & \\ {e}_{i} = {a}_{i} cos ( {w}_{i} t + {ϕ}_{i} ) , i = 1 , 2 , 3 & ( 12 )\end{matrix}$$

$$\begin{matrix}[ Equation 13 ] & \\ {e}_{i} = {a}_{i} cos ( {w}_{i} t + {ϕ}_{i} + {a}_{1 i} ) , i = 1 , 2 , 3 & ( 13 )\end{matrix}$$

$$\begin{matrix}[ Equation 14 ] & \\ {e}_{i} = {a}_{i} cos ( {w}_{i} t + {ϕ}_{i} + {a}_{2 i} ) , i = 1 , 2 , 3 & ( 14 )\end{matrix}$$

$$\begin{matrix}[ Equation 15 ] & \\ {e}_{i} = {a}_{i} cos ( {w}_{i} t + {ϕ}_{i} + {a}_{3 i} ) , i = 1 , 2 , 3 & ( 15 )\end{matrix}$$

$$\begin{matrix}[ Equation 16 ] & \\ {ϕ}_{2}^{″} = \frac{1}{Δ {ω}^{2}} ( {tan}^{- 1} ( \frac{2 cos ( Δ {ϕ}_{\text{?}} )}{cos ( Δ {ϕ}_{\text{?}} ) + cos ( Δ {ϕ}_{\text{?}} )} ( \frac{{E}_{beat} ( {ϕ}_{\text{?}} ) - {E}_{beat} ( {ϕ}_{\text{?}} )}{{E}_{beat} ( 0 ) - {E}_{beat} ( {ϕ}_{\text{?}} )} - \frac{sin ( Δ {ϕ}_{\text{?}} ) + sin ( Δ {ϕ}_{\text{?}} )}{2 cos ( Δ {ϕ}_{\text{?}} )} ) ) - Δ {ϕ}_{\text{?}} ) & ( 16 )\end{matrix}$$

$$\begin{matrix}[ Equation 21 ] & \\ {ϕ}_{2}^{″} = \frac{1}{Δ {ω}^{2}} ( atan 2 ( \frac{2 cos ( Δ {ϕ}_{α 2} )}{cos ( Δ {ϕ}_{α 1} ) + cos ( Δ {ϕ}_{α 3} )} ( 2 cos ( Δ {ϕ}_{α 2} ) ( {E}_{beat} ( {ϕ}_{α 3} ) - {E}_{beat} ( {ϕ}_{α 1} ) ) - ( sin ( {Δϕ}_{α 1} ) + sin ( {Δϕ}_{α 3} ) ) ( {E}_{beat} ( 0 ) - {E}_{beat} ( {ϕ}_{α 2} ) ) ) , 2 cos ( Δ {ϕ}_{α 2} ) ( {E}_{beat} ( 0 ) - {E}_{beat} ( {ϕ}_{α 2} ) ) ) - Δ {ϕ}_{α 2} ) & ( 21 )\end{matrix}$$

$$\text{?} \text{indicates text missing or illegible when filed}$$

(In Equations (12), (13), (14), (15), (16), and (21), aᵢ represent amplitudes, ωᵢ represent angular frequencies, φᵢ represent phases, t represents a time, and ω₂−ω₁=ω₃−ω₂=Δω is established, α₁ᵢ are phase offsets of the second 3-tone signal, and φ_{α1}=α₁₃−2α₁₂+α₁₁ is established when a second-order difference of α₁ᵢ is represented by φ_{α1}, α₂ᵢ are phase offsets of the third 3-tone signal, and φ_{α2}=α₂₃−2α₂₂+α₂₁ is established when a second-order difference of α₂ᵢ is represented by φ_{α2}, α₃ᵢ are phase offsets of the fourth 3-tone signal, and φ_{α3}=α₃₃−2α₃₂+α₃₁ is established when a second-order difference of α₃ᵢ is represented by φ_{α3}, φ_{α1}=π/2+Δφ_{α1}+Δφ_{α2}, φ_{α2}=π+2Δφ_{α2}, and φ_{α3}=3π/2+Δφ_{α3}+Δφ_{α2} are established, E_{beat}(0) represents a value that is obtained from a voltage value measured by the voltmeter and that is proportional to power of the signal output from the first detector, in a case where the first 3-tone signal is detected by the first detector, E_{beat}(φ_{α1}) represents a value that is obtained from a voltage value measured by the voltmeter and that is proportional to power of the signal output from the first detector, in a case where the second 3-tone signal in which the second-order difference of α₁ᵢ is set to φ_{α1} is detected by the first detector, E_{beat}(φ_{α2}) represents a value that is obtained from a voltage value measured by the voltmeter and that is proportional to power of the signal output from the first detector, in a case where the third 3-tone signal in which the second-order difference of α₂ᵢ is set to φ_{α2} is detected by the first detector, and E_{beat}(φ_{α3}) represents a value that is obtained from a voltage value measured by the voltmeter and that is proportional to power of the signal output from the first detector, in a case where the fourth 3-tone signal in which the second-order difference of α₃ᵢ is set to φ_{α3} is detected by the first detector.)

With this configuration, power of a beat component of the angular frequency Δω or a value obtained by adding an offset to the power is measured by the second detector for the 3-tone signals of four patterns having different phase offsets represented by Equations (12), (13), (14), and (15), and as a result, a phase relationship (second-order differential value) of the 3 tones represented by Equation (16) or Equation (21) can be calculated even in a case where each tone has an arbitrary and unknown amplitude. By using the a tan 2 function in Equation (21), a phase measurement range becomes wider than in a case where the tan⁻¹ function in Equation (16) is used. Accordingly, it is possible to provide a phase characteristic measurement apparatus that can realize a phase measurement at a relatively low cost without increasing the scale of the apparatus by using a detector and a voltmeter that do not require a high-speed trigger operation. In this configuration, the phase calculator has a characteristic of not being affected by a direct current offset during a voltage measurement and a BPF for extracting an angular frequency Δω component of a beat is not necessary. However, it is desirable to use the BPF in order to improve S/N.

In order to achieve the above object, a phase characteristic measurement apparatus according to the present invention includes a first detector (11) that receives and detects a first 2-tone signal obtained by combining two waves e₁ and e₂ represented by Equation (22), a second 2-tone signal obtained by combining two waves e₂ and e₃ represented by Equation (23), a first 3-tone signal obtained by combining three waves e₁, e₂, and e₃ represented by Equation (24), and a second 3-tone signal obtained by combining three waves e₁, e₂, and e₃ represented by Equation (25) as a signal for phase measurements, respectively, a band-pass filter (12) that, among signals output from the first detector, allows a frequency component of an angular frequency difference Δω between waves with adjacent frequencies of each of the signals for phase measurements to pass and blocks a frequency component twice the angular frequency difference Lw and a direct current component, a second detector (13) that detects a signal that has passed through the band-pass filter, a voltmeter (14) that measures a voltage of a signal output from the second detector, and a phase calculator (15) that calculates a phase φ₂″ represented by Equation (26) or Equation (31).

$$\begin{matrix}[ Equation 22 ] & \\ {e}_{i} = {a}_{i} cos ( {w}_{i} t + {ϕ}_{i} + {γ}_{i} ) , i = 1 , 2 & ( 22 )\end{matrix}$$

$$\begin{matrix}[ Equation 23 ] & \\ {e}_{i} = {a}_{i} cos ( {w}_{i} t + {ϕ}_{i} + {γ}_{i} ) , i = 2 , 3 & ( 23 )\end{matrix}$$

$$\begin{matrix}[ Equation 24 ] & \\ {e}_{i} = {a}_{i} cos ( {w}_{i} t + {ϕ}_{i} ) , i = 1 , 2 , 3 & ( 24 )\end{matrix}$$

$$\begin{matrix}[ Equation 25 ] & \\ {e}_{i} = {a}_{i} cos ( {w}_{i} t + {ϕ}_{i} + {α}_{1 i} ) , i = 1 , 2 , 3 & ( 25 )\end{matrix}$$

$$\begin{matrix}[ Equation 26 ] & \\ {ϕ}_{2}^{″} = \frac{1}{Δ {ω}^{2}} {tan}^{- 1} ( \frac{1}{cos ( Δ {ϕ}_{α 1} )} ( - \frac{{E}_{beat} ( {ϕ}_{\text{?}} ) - {E}_{beat} ( \text{?} = 0 ) - {E}_{beat} ( \text{?} = 0 )}{{E}_{beat} ( 0 ) - {E}_{beat} ( \text{?} = 0 ) - {E}_{beat} ( \text{?} = 0 )} - sin ( {Δϕ}_{\text{?}} ) ) ) & ( 26 )\end{matrix}$$

$$\begin{matrix}[ Equation 31 ] & \\ {ϕ}_{2}^{″} = \frac{1}{Δ {ω}^{2}} atan 2 ( \frac{1}{cos ( Δ {ϕ}_{α 1} )} ( - {E}_{beat} ( {ϕ}_{α 1} ) + {E}_{beat} ( {α}_{3} = 0 ) + {E}_{beat} ( {α}_{1} = 0 ) - sin ( Δ {ϕ}_{α 1} ) ( {E}_{beat} ( 0 ) - {E}_{beat} ( {α}_{3} = 0 ) - {E}_{beat} ( {α}_{1} = 0 ) ) ) , {E}_{beat} ( 0 ) - {E}_{beat} ( {α}_{3} = 0 ) - {E}_{beat} ( {α}_{1} = 0 ) ) & ( 31 )\end{matrix}$$

$$\text{?} \text{indicates text missing or illegible when filed}$$

(In Equations (22), (23), (24), (25), (26), and (31), αᵢ represent amplitudes, ωᵢ represent angular frequencies, φᵢ represent phases, γᵢ represent arbitrary phases, t represents a time, and ω₂−ω₁=ω₃−ω₂=Δω is established, α₁ᵢ are phase offsets of the second 3-tone signal, and φ_{α1}=α₁₃−2α₁₂+α₁₁ is established when a second-order difference of α₁ᵢ is represented by φ_{α1}, φ_{α1}=π/2+Δφ_{α1} is established, E_{beat}(φ_{α1}) represents a value that is obtained from a voltage value measured by the voltmeter and that is proportional to power of the signal that has passed through the band-pass filter, in a case where the second 3-tone signal in which the second-order difference of α₁ᵢ is set to φ_{α1} is detected by the first detector, E_{beat}(0) represents a value that is obtained from a voltage value measured by the voltmeter and that is proportional to power of the signal that has passed through the band-pass filter, in a case where the first 3-tone signal is detected by the first detector, E_{beat}(a₁=0) represents a value that is obtained from a voltage value measured by the voltmeter and that is proportional to power of the signal that has passed through the band-pass filter, in a case where the second 2-tone signal is detected by the first detector, and E_{beat}(a₃=0) represents a value that is obtained from a voltage value measured by the voltmeter and that is proportional to power of the signal that has passed through the band-pass filter, in a case where the first 2-tone signal is detected by the first detector.)

With this configuration, power of a beat component of the angular frequency Δω is measured by the second detector for the signal for phase measurements of four patterns represented by Equations (22), (23), (24), and (25), and as a result, a phase relationship (second-order differential value) of the 3 tones represented by Equation (26) or Equation (31) can be calculated even in a case where the amplitude of each tone signal is arbitrary and unknown. Specifically, offset components in case of 3-tone measurements are subtracted to obtain the phase by measuring beat power of the 3-tone signals of two patterns having different phase offsets and measuring beat power of the 2-tone signals of two patterns in which one tone among the 3 tones is zero. By using the a tan 2 function in Equation (31), a phase measurement range becomes wider than in a case where the tan⁻¹ function in Equation (26) is used. Accordingly, it is possible to provide a phase characteristic measurement apparatus that can realize a phase measurement at a relatively low cost without increasing the scale of the apparatus by using a detector and a voltmeter that do not require a high-speed trigger operation.

In order to achieve the above object, a phase characteristic measurement apparatus according to the present invention includes a first detector (11) that receives and detects a first 2-tone signal obtained by combining two waves e₁ and e₂ represented by Equation (32), a second 2-tone signal obtained by combining two waves e₂ and e₃ represented by Equation (33), and a 3-tone signal obtained by combining three waves e₁, e₂, and e₃ represented by Equation (34) as a signal for phase measurements, respectively, a band-pass filter (12) that, among signals output from the first detector, allows a frequency component of an angular frequency difference Δω between waves with adjacent frequencies of each of the signals for phase measurements to pass and blocks a frequency component twice the angular frequency difference Δω and a direct current component, a second detector (13) that detects a signal that has passed through the band-pass filter, a voltmeter (14) that measures a voltage of a signal output from the second detector, and a phase calculator (15) that calculates a phase φ₂″ represented by Equation (35)

$$\begin{matrix}[ Equation 32 ] & \\ {e}_{i} = {a}_{i} cos ( {w}_{i} t + {ϕ}_{i} + {γ}_{i} ) , i = 1 , 2 & ( 32 )\end{matrix}$$

$$\begin{matrix}[ Equation 33 ] & \\ {e}_{i} = {a}_{i} cos ( {w}_{i} t + {ϕ}_{i} + {γ}_{i} ) , i = 2 , 3 & ( 33 )\end{matrix}$$

$$\begin{matrix}[ Equation 34 ] & \\ {e}_{i} = {a}_{i} cos ( {w}_{i} t + {ϕ}_{i} ) , i = 1 , 2 , 3 & ( 34 )\end{matrix}$$

$$\begin{matrix}[ Equation 35 ] & \\ {ϕ}_{2}^{″} = \frac{1}{Δ {ω}^{2}} {cos}^{- 1} ( \frac{{E}_{beat} ( 0 ) - {E}_{beat} ( {α}_{3} = 0 ) - {E}_{beat} ( {α}_{1} = 0 )}{2 \sqrt{{E}_{beat} ( {α}_{1} = 0 ) {E}_{beat} ( {α}_{3} = 0 )}} ) & ( 35 )\end{matrix}$$

(In Equations (32), (33), (34), and (35), αᵢ represent amplitudes, ωᵢ represent angular frequencies, φᵢ represent phases, γᵢ represent arbitrary phases, t represents a time, and ω₂−ω₁=ω₃−ω₂=Δω is established, E_{beat}(0) represents a value that is obtained from a voltage value measured by the voltmeter and that is proportional to power of the signal that has passed through the band-pass filter, in a case where the 3-tone signal is detected by the first detector, E_{beat}(a₁=0) represents a value that is obtained from a voltage value measured by the voltmeter and that is proportional to power of the signal that has passed through the band-pass filter, in a case where the second 2-tone signal is detected by the first detector, and E_{beat}(a₃=0) represents a value that is obtained from a voltage value measured by the voltmeter and that is proportional to power of the signal that has passed through the band-pass filter, in a case where the first 2-tone signal is detected by the first detector.)

With this configuration, power of a beat component of the angular frequency Δω is measured by the second detector for the signal for phase measurements of three patterns represented by Equations (32), (33), and (34), and as a result, a phase relationship (second-order differential value) of the 3 tones represented by Equation (35) can be calculated even in a case where each tone has an arbitrary and unknown amplitude. Specifically, an offset component in a case of a 3-tone measurement is subtracted and an amplitude value in the 3-tone measurement is divided by measuring beat power of the 3-tone signal and measuring beat power of the 2-tone signals of two patterns in which one tone among the 3 tones is zero, and a phase can be calculated at by three measurements. Accordingly, it is possible to provide a phase characteristic measurement apparatus that can realize a phase measurement at a relatively low cost without increasing the scale of the apparatus by using a detector and a voltmeter that do not require a high-speed trigger operation.

A signal generator according to the present invention includes a high-frequency signal generation unit (2) that generates a high-frequency signal and the signal for phase measurements, a coupler (3) that branches a signal output from the high-frequency signal generation unit and outputs one signal as an output signal, and the phase characteristic measurement apparatus (1) according to any one of the aspects in which, when the high-frequency signal generation unit generates the signal for phase measurements, the other signal branched by the coupler is input, and the phase φ₂″ is measured from the input signal for phase measurements to measure a phase characteristic of the high-frequency signal generation unit, in which when the high-frequency signal generation unit generates the high-frequency signal, a phase characteristic of the high-frequency signal is corrected based on the phase characteristic of the high-frequency signal generation unit measured by the phase characteristic measurement apparatus.

With this configuration, the same effects as those described above for the phase characteristic measurement apparatus can be obtained, and the phase characteristic of the high-frequency signal generation unit can be corrected based on the phase characteristic of the high-frequency signal generation unit measured by the phase characteristic measurement apparatus, making it possible to generate a high-frequency signal with a good phase characteristic.

A signal analyzer according to the present invention includes a reference signal generation unit (20) that generates a reference signal and the signal for phase measurements, a coupler (3) that branches a signal output from the reference signal generation unit, the phase characteristic measurement apparatus (1) according to any one of the aspects in which, when the reference signal generation unit generates the signal for phase measurements, one signal branched by the coupler is input, and the phase φ₂″ is measured from the input signal for phase measurements to measure a phase characteristic of the reference signal generation unit, a switch (4) that selects one signal of the other signal branched by the coupler or an input signal, and a high-frequency signal analysis unit (5) that analyzes the signal selected by the switch, in which a phase characteristic of the high-frequency signal analysis unit is calculated from a phase characteristic of the reference signal measured by the high-frequency signal analysis unit when the reference signal generation unit generates the reference signal and the other signal branched by the coupler is selected by the switch, and the phase characteristic of the reference signal generation unit measured by the phase characteristic measurement apparatus, a phase characteristic in a case where the high-frequency signal analysis unit analyzes the input signal is corrected based on the calculated phase characteristic of the high-frequency signal analysis unit, when the input signal is selected by the switch, and signal analysis of the input signal is performed with the corrected phase characteristic.

As described above, the phase characteristic of the reference signal generation unit is measured by the phase characteristic measurement apparatus, and the reference signal having the known phase characteristic is input to the high-frequency signal analysis unit from the reference signal generation unit, so that the phase characteristic of the high-frequency signal analysis unit is measured, the phase characteristic of the high-frequency signal analysis unit is corrected based on the measured phase characteristic of the high-frequency signal analysis unit, and the signal analysis of the input signal is performed by the high-frequency signal analysis unit with the corrected phase characteristic. Therefore, the same effects as those described above for the phase characteristic measurement apparatus, and the signal analysis with corrected phase characteristic can be performed, thereby improving the quality of the analysis.

In order to achieve the above object, a phase characteristic measurement method according to the present invention includes a signal for phase measurements generation step of generating, as a signal for phase measurements, a first 3-tone signal obtained by combining three waves e₁, e₂, and e₃ represented by Equation (36) and a second 3-tone signal obtained by combining three waves e₁, e₂, and e₃ represented by Equation (37), a first detection step of detecting the signal for phase measurements, a band-pass filter step of, among the signals obtained in the first detection step, allowing a frequency component of an angular frequency difference Δω between waves with adjacent frequencies of each of the signals for phase measurements to pass and blocking a frequency component twice the angular frequency difference Δω and a direct current component, a second detection step of detecting a signal that has passed in the band-pass filter step, a voltage measurement step of measuring a voltage of a signal obtained in the second detection step, and a phase calculation step of calculating a phase φ₂″ represented by Equation (38).

$$\begin{matrix}[ Equation 36 ] & \\ {e}_{i} {=}_{} cos ( {w}_{i} t + {ϕ}_{i} ) , i = 1 , 2 , 3 & ( 36 )\end{matrix}$$

$$\begin{matrix}[ Equation 37 ] & \\ {e}_{i} {=}_{} {a}_{i} cos ( {w}_{i} t + {ϕ}_{i} + {a}_{i} ) , i = 1 , 2 , 3 & ( 37 )\end{matrix}$$

$$\begin{matrix}[ Equation 38 ] & \\ {ϕ}_{2}^{″} = \{ \begin{matrix}\frac{2}{Δ {ω}^{2}} {tan}^{- 1} ( \frac{\begin{matrix}\sqrt{\frac{{E}_{beat} ( {ϕ}_{α} )}{{E}_{beat} ( 0 )}} + \\ cos ( \frac{{ϕ}_{α}}{2} )\end{matrix}}{sin ( \frac{{ϕ}_{α}}{2} )} ) , & π - {ϕ}_{α} \leq {ϕ}_{3} - 2 {ϕ}_{2} + {ϕ}_{1} \leq π \\ \frac{2}{Δ {ω}^{2}} {tan}^{- 1} ( \frac{\begin{matrix}- \sqrt{\frac{{E}_{beat} ( {ϕ}_{α} )}{{E}_{beat} ( 0 )}} + \\ cos ( \frac{{ϕ}_{α}}{2} )\end{matrix}}{sin ( \frac{{ϕ}_{α}}{2} )} ) , & - π \leq {ϕ}_{3} - 2 {ϕ}_{2} + {ϕ}_{1} \leq π - {ϕ}_{α}\end{matrix} & ( 38 )\end{matrix}$$

(In Equations (36), (37), and (38), ow represent angular frequencies, φᵢ represent phases, t represents a time, and ω₂−ω₁=ω₃−ω₂=Δω is established, αᵢ are phase offsets of the second 3-tone signal, and φ_{α}=α₃−2α₂+α₁ᵢ is established when a second-order difference of αᵢ is represented by φ_{α}, E_{beat}(φ_{α}) represents a value that is obtained from a voltage value measured in the voltage measurement step and that is proportional to power of the signal that has passed in the band-pass filter step in a case where the second 3-tone signal in which the second-order difference of αᵢ is set to φ_{α} is detected in the first detection step, and E_{beat}(0) represents a value that is obtained from a voltage value measured in the voltage measurement step and that is proportional to power of the signal that has passed in the band-pass filter step in a case where the first 3-tone signal is detected in the first detection step.)

With this configuration, power of a beat component of the angular frequency Δω is measured by the second detector for the 3-tone signals of two patterns of the first 3-tone signal represented by Equation (36) in which all 3 tones have the equal amplitude, and the second 3-tone signal represented by Equation (37), which has the equal amplitude as the first 3-tone signal and a phase offset with respect to the first 3-tone signal, and as a result, a phase relationship (second-order differential value) of the 3 tones represented by Equation (38) can be calculated. Accordingly, it is possible to provide a phase characteristic measurement method that can realize a phase measurement at a relatively low cost without increasing the scale of the apparatus by using a detector and a voltmeter that do not require a high-speed trigger operation. In this phase characteristic measurement method, a phase can be measured by two times of measurements.

In order to achieve the above object, a phase characteristic measurement method according to the present invention includes a signal for phase measurements generation step of generating, as a signal for phase measurements, a first 3-tone signal obtained by combining three waves e₁, e₂, and e₃ represented by Equation (39), a second 3-tone signal obtained by combining three waves e₁, e₂, and e₃ represented by Equation (40), and a third 3-tone signal obtained by combining three waves e₁, e₂, and e₃ represented by Equation (41), a first detection step of detecting the signal for phase measurements, a second detection step of detecting a signal obtained in the first detection step, a voltage measurement step of measuring a voltage of a signal obtained in the second detection step, and a phase calculation step of calculating a phase φ₂″ represented by Equation (42) or Equation (46).

$$\begin{matrix}[ Equation 39 ] & \\ {e}_{i} {=}_{} {a}_{i} cos ( {w}_{i} t + {ϕ}_{i} ) , i = 1 , 2 , 3 & ( 39 )\end{matrix}$$

$$\begin{matrix}[ Equation 40 ] & \\ {e}_{i} {=}_{} {a}_{i} cos ( {w}_{i} t + {ϕ}_{i} + {a}_{1 i} ) , i = 1 , 2 , 3 & ( 40 )\end{matrix}$$

$$\begin{matrix}[ Equation 41 ] & \\ {e}_{i} {=}_{} {a}_{i} cos ( {w}_{i} t + {ϕ}_{i} + {a}_{2 i} ) , i = 1 , 2 , 3 & ( 41 )\end{matrix}$$

$$\begin{matrix}[ Equation 42 ] & \\ {ϕ}_{1}^{″} = \frac{1}{Δ {ω}^{1}} ( {tan}^{- 1} ( \frac{cos ( Δ {ϕ}_{\text{?}} )}{cos ( Δ {ϕ}_{\text{?}} ) + sin ( Δ {ϕ}_{\text{?}} )} ( \frac{{E}_{beat} ( 0 ) - 2 {E}_{beat} ( {ϕ}_{\text{?}} ) + {E}_{beat} ( {ϕ}_{\text{?}} )}{{E}_{beat} ( 0 ) - {E}_{beat} ( {ϕ}_{\text{?}} )} - \frac{sin ( Δ {ϕ}_{\text{?}} )}{cos ( Δ {ϕ}_{\text{?}} )} ) ) - Δ {ϕ}_{\text{?}} ) & ( 42 )\end{matrix}$$

$$\begin{matrix}[ Equation 46 ] & \\ {ϕ}_{2}^{″} = \frac{1}{Δ {ω}^{2}} ( atan 2 ( \frac{cos ( Δ {ϕ}_{α 2} )}{cos ( Δ {ϕ}_{α 1} ) + sin ( Δ {ϕ}_{α 2} )} ( cos ( Δ {ϕ}_{α 2} ) ( {E}_{beat} ( 0 ) - 2 {E}_{beat} ( {ϕ}_{α 1} ) + {E}_{beat} ( {ϕ}_{α 2} ) ) - sin ( Δ {ϕ}_{α 1} ) ( {E}_{beat} ( 0 ) - {E}_{beat} ( {ϕ}_{α 2} ) ) ) , cos ( Δ {ϕ}_{α 2} ) ( {E}_{beat} ( 0 ) - {E}_{beat} ( {ϕ}_{α 2} ) ) ) - Δ {ϕ}_{α 2} ) & ( 46 )\end{matrix}$$

$$\text{?} \text{indicates text missing or illegible when filed}$$

(In Equations (39), (40), (41), (42), and (46), aᵢ represent amplitudes, ωᵢ represent angular frequencies, φᵢ represent phases, t represents a time, and ω₂−ω₁=ω₃−ω₂=Δω is established, α₁ᵢ are phase offsets of the second 3-tone signal, and φ_{α1}=α₁₃−2α₁₂+α₁₁ is established when a second-order difference of α₁ᵢ is represented by φ_{α1}, α₂ᵢ are phase offsets of the third 3-tone signal, and φ_{α2}=α₂₃−2α₂₂+α₂₁ is established when a second-order difference of α₂ᵢ is represented by φ_{α2}, φ_{α1}=π/2+Δφ_{α1}+Δφ_{α2}, and φ_{α2}=π+2Δφ_{α2} are established, E_{beat}(0) represents a value that is obtained from a voltage value measured in the voltage measurement step and that is proportional to power of the signal obtained in the first detection step in a case where the first 3-tone signal is detected in the first detection step, E_{beat}(φ_{α1}) represents a value that is obtained from a voltage value measured in the voltage measurement step and that is proportional to power of the signal obtained in the first detection step in a case where the second 3-tone signal in which the second-order difference of α₁ᵢ is set to φ_{α1} is detected in the first detection step, and E_{beat}(φ_{α2}) represents a value that is obtained from a voltage value measured in the voltage measurement step and that is proportional to power of the signal obtained in the first detection step in a case where the third 3-tone signal in which the second-order difference of α₂ᵢ is set to φ_{α2} is detected in the first detection step.)

With this configuration, power of a beat component of the angular frequency Δω or a value obtained by adding an offset to the power is measured in the second detection step for the 3-tone signals of three patterns having different phase offsets represented by Equations (39), (40), and (41), and as a result, a phase relationship (second-order differential value) of the 3 tones represented by Equation (42) or Equation (46) can be calculated even in a case where the amplitudes of the 3 tones are unknown and are unequal amplitudes. By using the a tan 2 function in Equation (46), a phase measurement range becomes wider than in a case where the tan⁻¹ function in Equation (42) is used. Accordingly, it is possible to provide a phase characteristic measurement method that can realize a phase measurement at a relatively low cost without using a large-scale apparatus by using a detector and a voltmeter that do not require a high-speed trigger operation. In this method, the phase calculation step that has a characteristic of not being affected by a direct current offset during a voltage measurement and a band-pass filter step for extracting an angular frequency Δω component of a beat is not necessary. However, it is desirable to use a band-pass filter step in order to improve S/N.

In order to achieve the above object, a phase characteristic measurement method according to the present invention includes a signal for phase measurements generation step of generating, as a signal for phase measurements, a first 3-tone signal obtained by combining three waves e₁, e₂, and e₃ represented by Equation (47), a second 3-tone signal obtained by combining three waves e₁, e₂, and e₃ represented by Equation (48), a third 3-tone signal obtained by combining three waves e₁, e₂, and e₃ represented by Equation (49), and a fourth 3-tone signal obtained by combining three waves e₁, e₂, and e₃ represented by Equation (50), a first detection step of detecting the signal for phase measurements, a second detection step of detecting a signal obtained in the first detection step, a voltage measurement step of measuring a voltage of a signal obtained in the second detection step, and a phase calculation step of calculating a phase φ₂″ represented by Equation (51) or Equation (56).

$$\begin{matrix}[ Equation 47 ] & \\ {e}_{i} {=}_{} {a}_{i} cos ( {w}_{i} t + {ϕ}_{i} ) , i = 1 , 2 , 3 & ( 47 )\end{matrix}$$

$$\begin{matrix}[ Equation 48 ] & \\ {e}_{i} {=}_{} {a}_{i} cos ( {w}_{i} t + {ϕ}_{i} + {α}_{1 i} ) , i = 1 , 2 , 3 & ( 48 )\end{matrix}$$

$$\begin{matrix}[ Equation 49 ] & \\ {e}_{i} {=}_{} {a}_{i} cos ( {w}_{i} t + {ϕ}_{i} + {α}_{2 i} ) , i = 1 , 2 , 3 & ( 49 )\end{matrix}$$

$$\begin{matrix}[ Equation 50 ] & \\ {e}_{i} {=}_{} {a}_{i} cos ( {w}_{i} t + {ϕ}_{i} + {α}_{3 i} ) , i = 1 , 2 , 3 & ( 50 )\end{matrix}$$

$$\begin{matrix}[ Equation 51 ] & \\ {ϕ}_{2}^{″} = \frac{1}{Δ {ω}^{2}} ( {tan}^{- 1} ( \frac{2 cos ( Δ {ϕ}_{\text{?}} )}{cos ( Δ {ϕ}_{\text{?}} ) + cos ( Δ {ϕ}_{\text{?}} )} ( \frac{{E}_{beat} ( {ϕ}_{\text{?}} ) - {E}_{beat} ( {ϕ}_{\text{?}} )}{{E}_{beat} ( 0 ) - {E}_{beat} ( {ϕ}_{\text{?}} )} - \frac{sin ( Δ {ϕ}_{\text{?}} ) + sin ( Δ {ϕ}_{\text{?}} )}{2 cos ( Δ {ϕ}_{\text{?}} )} ) ) - Δ {ϕ}_{\text{?}} ) & ( 51 )\end{matrix}$$

$$\begin{matrix}[ Equation 56 ] & \\ {ϕ}_{2}^{″} = \frac{1}{Δ {ω}^{2}} ( atan 2 ( \frac{2 cos ( Δ {ϕ}_{α 2} )}{cos ( Δ {ϕ}_{α 1} ) + cos ( Δ {ϕ}_{α 2} )} ( 2 cos ( Δ {ϕ}_{α 2} ) ( {E}_{beat} ( {ϕ}_{α 3} ) - {E}_{beat} ( {ϕ}_{α 1} ) ) - ( sin ( {Δϕ}_{α 1} ) + sin ( {Δϕ}_{α 3} ) ) ( {E}_{beat} ( 0 ) - {E}_{beat} ( {ϕ}_{α 2} ) ) ) , 2 cos ( Δ {ϕ}_{α 2} ) ( {E}_{beat} ( 0 ) - {E}_{beat} ( {ϕ}_{α 2} ) ) ) - Δ {ϕ}_{α 2} ) & ( 56 )\end{matrix}$$

$$\text{?} \text{indicates text missing or illegible when filed}$$

(In Equations (47), (48), (49), (50), (51), and (56), aᵢ represent amplitudes, ωᵢ represent angular frequencies, φᵢ represent phases, t represents a time, and ω₂−ω₁=ω₃−ω₂=Δω is established, α₁ᵢ are phase offsets of the second 3-tone signal, and φ_{α1}=α₁₃−2α₁₂+α₁₁ is established when a second-order difference of α₁ᵢ is represented by φ_{α1}, α₂ᵢ are phase offsets of the third 3-tone signal, and φ_{α2}=α₂₃−2α₂₂+α₂₁ is established when a second-order difference of α₂₁ is represented by φ_{α2}, α₃ᵢ are phase offsets of the fourth 3-tone signal, and φ_{α3}=α₃₃−2α₃₂+α₃₁ is established when a second-order difference of α₃ᵢ is represented by φ_{α3}, φ_{α1}=π/2+Δφ_{α1}+Δφ_{α2}, φ_{α2}=π+2Δφ_{α2}, and φ_{α3}=3π/2+Δφ_{α3}+Δφ_{α2} are established, E_{beat}(0) represents a value that is obtained from a voltage value measured in the voltage measurement step and that is proportional to power of the signal obtained in the first detection step in a case where the first 3-tone signal is detected in the first detection step, E_{beat}(φ_{α1}) represents a value that is obtained from a voltage value measured in the voltage measurement step and that is proportional to power of the signal obtained in the first detection step in a case where the second 3-tone signal in which the second-order difference of α₁ᵢ is set to φ_{α1} is detected in the first detection step, E_{beat}(φ_{α2}) represents a value that is obtained from a voltage value measured in the voltage measurement step and that is proportional to power of the signal obtained in the first detection step in a case where the third 3-tone signal in which the second-order difference of α₂₁ is set to φ_{α2} is detected in the first detection step, and E_{beat}(φ_{α3}) represents a value that is obtained from a voltage value measured in the voltage measurement step and that is proportional to power of the signal obtained in the first detection step in a case where the fourth 3-tone signal in which the second-order difference of α₃ᵢ is set to φ_{α3} is detected in the first detection step.)

With this configuration, power of a beat component of the angular frequency Δω or a value obtained by adding an offset to the power is measured in the second detection step for the 3-tone signals of four patterns having different phase offsets represented by Equations (47), (48), (49), and (50), and as a result, a phase relationship (second-order differential value) of the 3 tones represented by Equation (51) or Equation (56) can be calculated even in a case where each tone has an arbitrary and unknown amplitude. By using the a tan 2 function in Equation (56), a phase measurement range becomes wider than in a case where the tan⁻¹ function in Equation (51) is used. Accordingly, it is possible to provide a phase characteristic measurement method that can realize a phase measurement at a relatively low cost without using a large-scale apparatus by using a detector and a voltmeter that do not require a high-speed trigger operation. In this method, the phase calculation step has a characteristic of not being affected by a direct current offset during a voltage measurement and a band-pass filter step for extracting an angular frequency Δω component of a beat is not necessary. However, it is desirable to use a band-pass filter step in order to improve S/N.

In order to achieve the above object, a phase characteristic measurement method according to the present invention includes a signal for phase measurements generation step of generating, as a signal for phase measurements, a first 2-tone signal obtained by combining two waves e₁ and e₂ represented by Equation (57), a second 2-tone signal obtained by combining two waves e₂ and e₃ represented by Equation (58), a first 3-tone signal obtained by combining three waves e₁, e₂, and e₃ represented by Equation (59), and a second 3-tone signal obtained by combining three waves e₁, e₂, and e₃ represented by Equation (60), a first detection step of detecting the signal for phase measurements, a band-pass filter step of, among the signals obtained in the first detection step, allowing a frequency component of an angular frequency difference Δω between waves with adjacent frequencies of each of the signals for phase measurements to pass and blocking a frequency component twice the angular frequency difference Δω and a direct current component, a second detection step of detecting a signal that has passed in the band-pass filter step, a voltage measurement step of measuring a voltage of a signal obtained in the second detection step, and a phase calculation step of calculating a phase φ₂″ represented by Equation (61) or Equation (66).

$$\begin{matrix}[ Equation 57 ] & \\ {e}_{i} {=}_{} {a}_{i} cos ( {w}_{i} t + {ϕ}_{i} + {γ}_{i} ) , i = 1 , 2 & ( 57 )\end{matrix}$$

$$\begin{matrix}[ Equation 58 ] & \\ {e}_{i} {=}_{} {a}_{i} cos ( {w}_{i} t + {ϕ}_{i} + {γ}_{i} ) , i = 2 , 3 & ( 58 )\end{matrix}$$

$$\begin{matrix}[ Equation 59 ] & \\ {e}_{i} {=}_{} {a}_{i} cos ( {w}_{i} t + {ϕ}_{i} ) , i = 1 , 2 , 3 & ( 59 )\end{matrix}$$

$$\begin{matrix}[ Equation 609 ] & \\ {e}_{i} {=}_{} {a}_{i} cos ( {w}_{i} t + {ϕ}_{i} + {ϕ}_{1 i} ) , i = 1 , 2 , 3 & ( 60 )\end{matrix}$$

$$\begin{matrix}[ Equation 61 ] & \\ \begin{matrix}{ϕ}_{2}^{″} = \frac{1}{Δ {ω}^{2}} {tan}^{- 1} ( \frac{1}{cos ( Δ {ϕ}_{α 1} )} ( - \frac{{E}_{beat} ( {ϕ}_{\text{?}} ) - {E}_{beat} ( \text{?} = 0 ) - {E}_{beat} ( \text{?} = 0 )}{{E}_{beat} ( 0 ) - {E}_{beat} ( \text{?} = 0 ) - {E}_{beat} ( \text{?} = 0 )} - sin ( {Δϕ}_{\text{?}} ) ) ) & \end{matrix} & ( 61 )\end{matrix}$$

$$\begin{matrix}[ Equation 66 ] & \\ {ϕ}_{2}^{″} = \frac{1}{Δ {ω}^{2}} atan 2 ( \frac{1}{cos ( Δ {ϕ}_{α 1} )} ( - {E}_{beat} ( {ϕ}_{α 1} ) + {E}_{beat} ( {α}_{3} = 0 ) + {E}_{beat} ( {α}_{1} = 0 ) - sin ( Δ {ϕ}_{α 1} ) ( {E}_{beat} ( 0 ) - {E}_{beat} ( {α}_{3} = 0 ) - {E}_{beat} ( {α}_{1} = 0 ) ) ) , {E}_{beat} ( 0 ) - {E}_{beat} ( {α}_{3} = 0 ) - {E}_{beat} ( {α}_{1} = 0 ) ) & ( 66 )\end{matrix}$$

$$\text{?} \text{indicates text missing or illegible when filed}$$

(In Equations (57), (58), (59), (60), (61), and (66), αᵢ represent amplitudes, ωᵢ represent angular frequencies, φᵢ represent phases, γᵢ represent arbitrary phases, t represents a time, and ω₂−ω₁=ω₃−ω₂=ΔW is established, α₁ᵢ are phase offsets of the second 3-tone signal, and φ_{α1}=α₁₃−2α₁₂+α₁₁ is established when a second-order difference of α₁ᵢ is represented by φ_{α1}, φ_{α1}=π/2+Δφ_{α1} is established, E_{beat}(φ_{α1}) represents a value that is obtained from a voltage value measured in the voltage measurement step and that is proportional to power of the signal that has passed in the band-pass filter step in a case where the second 3-tone signal in which the second-order difference of α₁ᵢ is set to φ_{α1} is detected in the first detection step, E_{beat}(0) represents a value that is obtained from a voltage value measured in the voltage measurement step and that is proportional to power of the signal that has passed in the band-pass filter step in a case where the first 3-tone signal is detected in the first detection step, E_{beat}(a₁=0) represents a value that is obtained from a voltage value measured in the voltage measurement step and that is proportional to power of the signal that has passed in the band-pass filter step in a case where the second 2-tone signal is detected in the first detection step, and E_{beat}(a₃=0) represents a value that is obtained from a voltage value measured in the voltage measurement step and that is proportional to power of the signal that has passed in the band-pass filter step in a case where the first 2-tone signal is detected in the first detection step.)

With this configuration, power of a beat component of the angular frequency Δω is measured in the second detection step for the signal for phase measurements of four patterns represented by Equations (57), (58), (59), and (60), and as a result, a phase relationship (second-order differential value) of the 3 tones represented by Equation (61) or Equation (66) can be calculated even in a case where the amplitude of each tone signal is arbitrary and unknown. Specifically, offset components in case of 3-tone measurements are subtracted to obtain the phase by measuring beat power of the 3-tone signals of two patterns having different phase offsets and measuring beat power of the 2-tone signals of two patterns in which one tone among the 3 tones is zero. By using the a tan 2 function in Equation (66), a phase measurement range becomes wider than in a case where the tan⁻¹ function in Equation (61) is used. Accordingly, it is possible to provide a phase characteristic measurement method that can realize a phase measurement at a relatively low cost without using a large-scale apparatus by using a detector and a voltmeter that do not require a high-speed trigger operation.

In order to achieve the above object, a phase characteristic measurement method according to the present invention includes a signal for phase measurements generation step of generating, as a signal for phase measurements, a first 2-tone signal obtained by combining two waves e₁ and e₂ represented by Equation (67), a second 2-tone signal obtained by combining two waves e₂ and e₃ represented by Equation (68), and a 3-tone signal obtained by combining three waves e₁, e₂, and e₃ represented by Equation (69), a first detection step of detecting the signal for phase measurements, a band-pass filter step of, among the signals obtained in the first detection step, allowing a frequency component of an angular frequency difference Δω between waves with adjacent frequencies of each of the signals for phase measurements to pass and blocking a frequency component twice the angular frequency difference Δω and a direct current component, a second detection step of detecting a signal that has passed in the band-pass filter step, a voltage measurement step of measuring a voltage of a signal obtained in the second detection step, and a phase calculation step of calculating a phase φ₂″ represented by Equation (70)

$$[ Equation 67 ]$$

$$\begin{matrix}{e}_{i} = {a}_{i} cos ( {ω}_{i} t + {ϕ}_{i} + {γ}_{i} ) , & i = 1 , 2\end{matrix} \qquad ( 67 )$$

$$[ Equation 68 ]$$

$$\begin{matrix}{e}_{i} = {a}_{i} cos ( {ω}_{i} t + {ϕ}_{i} + {γ}_{i} ) , & i = 2 , 3\end{matrix} \qquad ( 68 )$$

$$[ Equation 69 ]$$

$$\begin{matrix}{e}_{i} = {a}_{i} cos ( {ω}_{i} t + {ϕ}_{i} ) , & i = 1 , 2\end{matrix} , 3 \qquad ( 69 )$$

$$[ Equation 70 ]$$

$${ϕ}_{2}^{′′} = \frac{1}{Δ {ω}^{2}} {cos}^{- 1} ( \frac{{E}_{heat} ( 0 ) - {E}_{beat} ( {a}_{3} = 0 ) - {E}_{beat} ( {a}_{1} = 0 )}{2 \sqrt{{E}_{beat} ( {a}_{1} = 0 ) {E}_{beat} ( {a}_{3} = 0 )}} ) \qquad ( 70 )$$

(In Equations (67), (68), (69), and (70), αᵢ represent amplitudes, ωᵢ represent angular frequencies, Di represent phases, γᵢ represent arbitrary phases, t represents a time, and ω₂−ω₁=ω₃−ω₂=Δω is established, E_{beat}(0) represents a value that is obtained from a voltage value measured in the voltage measurement step and that is proportional to power of the signal that has passed in the band-pass filter step in a case where the 3-tone signal is detected in the first detection step, E_{beat}(a₁=0) represents a value that is obtained from a voltage value measured in the voltage measurement step and that is proportional to power of the signal that has passed in the band-pass filter step in a case where the second 2-tone signal is detected in the first detection step, and E_{beat}(a₃=0) represents a value that is obtained from a voltage value measured in the voltage measurement step and that is proportional to power of the signal that has passed in the band-pass filter step in a case where the first 2-tone signal is detected in the first detection step.)

With this configuration, power of a beat component of the angular frequency Δω is measured in the second detection step for the signal for phase measurements of three patterns represented by Equations (67), (68), and (69), and as a result, a phase relationship (second-order differential value) of the 3 tones represented by Equation (70) can be calculated even in a case where each tone has an arbitrary and unknown amplitude. Specifically, an offset component in a case of a 3-tone measurement is subtracted and an amplitude value in the 3-tone measurement is divided by measuring beat power of the 3-tone signal and measuring beat power of the 2-tone signals of two patterns in which one tone among the 3 tones is zero, and a phase can be calculated at by three measurements. Accordingly, it is possible to provide a phase characteristic measurement method that can realize a phase measurement at a relatively low cost without using a large-scale apparatus by using a detector and a voltmeter that do not require a high-speed trigger operation.

A signal generation method according to the present invention includes the phase characteristic measurement method according to any one of the aspects in which the signal for phase measurements is generated by a high-frequency signal generation unit in the signal for phase measurements generation step, and the phase φ₂″ is measured from the signal for phase measurements generated in the signal for phase measurements generation step to measure a phase characteristic of the high-frequency signal generation unit, and a high-frequency signal generation step of generating a high-frequency signal by the high-frequency signal generation unit and outputting the high-frequency signal as an output signal, in which a phase characteristic of the high-frequency signal is corrected based on the phase characteristic of the high-frequency signal generation unit measured by the phase characteristic measurement method.

With this configuration, the same effects as those described above for the phase characteristic measurement method can be obtained, and the phase characteristic of the high-frequency signal can be corrected based on the phase characteristic of the high-frequency signal generation unit measured by the phase characteristic measurement method, making it possible to generate a high-frequency signal with a good phase characteristic.

In order to achieve the above object, a signal analysis method according to the present invention includes the phase characteristic measurement method according to any one of the aspects, in which the signal for phase measurements is generated by a reference signal generation unit in the signal for phase measurements generation step, and the phase φ₂″ is measured from the signal for phase measurements generated in the signal for phase measurements generation step to measure a phase characteristic of the reference signal generation unit, a reference signal generation step of generating a reference signal by the reference signal generation unit, a reference signal analysis step of measuring a phase characteristic of the reference signal by a high-frequency signal analysis unit, and a high-frequency signal analysis step of analyzing an input signal by the high-frequency signal analysis unit, in which a phase characteristic of the high-frequency signal analysis unit is calculated from the phase characteristic of the reference signal generation unit measured by the phase characteristic measurement method, and the phase characteristic of the reference signal measured in the reference signal analysis step, a phase characteristic in a case where analysis of the input signal is performed in the high-frequency signal analysis step is corrected based on the calculated phase characteristic of the high-frequency signal analysis unit, and signal analysis of the input signal is performed with the corrected phase characteristic.

As described above, the phase characteristic of the reference signal generation unit is measured by the phase characteristic measurement method, and the reference signal having the known phase characteristic is analyzed in the high-frequency signal analysis step, so that the phase characteristic of the high-frequency signal analysis unit is measured, the phase characteristic in a case where the signal analysis of the input signal is performed is corrected based on the measured phase characteristic of the high-frequency signal analysis unit. Therefore, the same effects as those described above for the phase characteristic measurement method, and the signal analysis with corrected phase characteristic can be performed, thereby improving the quality of the analysis.

### Advantage of the Invention

According to the present invention, it is possible to provide a phase characteristic measurement apparatus that can realize phase measurement at a relatively low cost without increasing the scale of an apparatus used for the phase measurement, a signal generator and a signal analyzer having the same, and a phase characteristic measurement method.

### BRIEF DESCRIPTION OF THE DRAWINGS

FIG. 1 is a diagram showing a configuration of a phase characteristic measurement system using a detector, according to an embodiment of the present invention.

FIG. 2 is a diagram showing a configuration of a phase characteristic measurement apparatus (3-tone equal amplitude and two times of measurement) according to the embodiment of the present invention.

FIG. 3 is a diagram showing a configuration of the phase characteristic measurement apparatus (3-tone unequal amplitude and three times of measurement) according to the embodiment of the present invention.

FIG. 4 is a diagram showing a configuration of the phase characteristic measurement apparatus (3-tone unequal amplitude and four times of measurement) according to the embodiment of the present invention.

FIG. 5 is a diagram showing a configuration of the phase characteristic measurement apparatus (3-tone unequal amplitude, 2-tone measurement combined, and four times of measurement) according to the embodiment of the present invention.

FIG. 6 is a diagram showing a configuration of the phase characteristic measurement apparatus (3-tone unequal amplitude, 2-tone measurement combined, and three measurement) according to the embodiment of the present invention.

FIG. 7 is a diagram showing a schematic configuration of a signal generator provided with the phase characteristic measurement apparatus according to the embodiment of the present invention.

FIG. 8 is a diagram showing a detailed configuration of the signal generator provided with the phase characteristic measurement apparatus according to the embodiment of the present invention.

FIG. 9 is a diagram showing another detailed configuration of the signal generator provided with the phase characteristic measurement apparatus according to the embodiment of the present invention.

FIG. 10 is a diagram showing a schematic configuration of a signal analyzer provided with the phase characteristic measurement apparatus according to the embodiment of the present invention.

FIG. 11 is a diagram showing a detailed configuration of the signal analyzer provided with the phase characteristic measurement apparatus according to the embodiment of the present invention.

### BEST MODE FOR CARRYING OUT THE INVENTION

Hereinafter, embodiments of the present invention will be described with reference to the drawings.

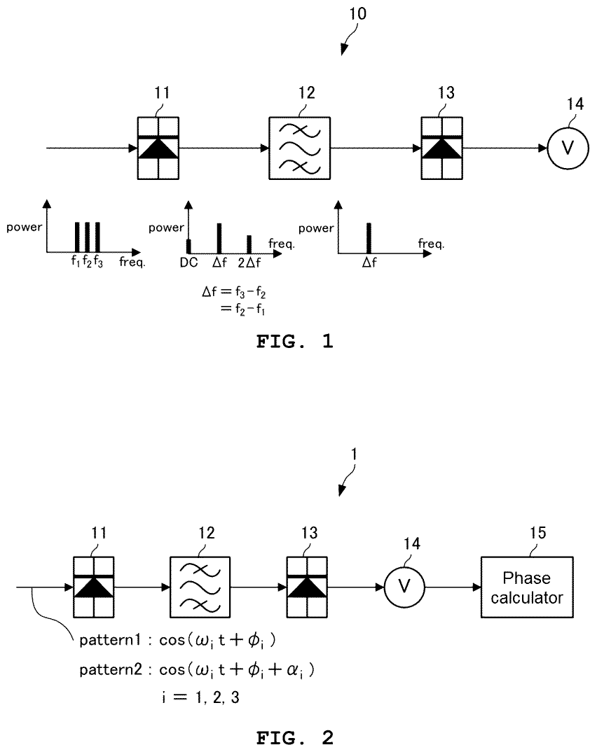

First, a measurement principle of a phase characteristic measurement system using a detector used in the embodiments of the present invention will be described. FIG. 1 shows a schematic configuration of a phase characteristic measurement system 10 according to the embodiments of the present invention. First, a 3-tone signal obtained by combining three waves (frequencies f₁, f₂, and f₃) in a high-frequency band is input to a first detector 11. The frequencies of each tone of the 3-tone signal are equally spaced (f₂−f₁=f₃−f₂). The first detector 11 performs square detection on the input 3-tone signal and outputs a detection result of a frequency lower than the frequencies of the 3-tone signal. Therefore, a DC component proportional to the average power of the 3-tone signal and a beat between each of the tones are generated from the first detector 11. A frequency of a beat between the wave of the frequency f₁ and the wave of the frequency f₂ is f₂−f₁, a frequency of a beat between the wave of the frequency f₂ and the wave of the frequency f₃ is f₃−f₂, and a frequency of a beat between the wave of the frequency f₁ and the wave of the frequency f₃ is f₃=f₁. Therefore, from the first detector 11, the DC component, a frequency component of a frequency spacing Δf (=f₂−f₁=f₃−f₂) of the adjacent waves, and a frequency component of a frequency spacing 2Δf (=f₃−f₁) of the waves at both ends are output. The band-pass filter (BPF) 12 removes the DC component and a frequency component twice the tone spacing αf (=f₂−f₁=f₃−f₂), and allows only the frequency component of the tone spacing to pass. That is, beat components of the frequencies of f₂−f₁ and f₃−f₂ are extracted by the BPF 12. As the BPF 12 need to block only the DC component and the component of the frequency 2Δf and allow the component of the frequency Of to pass, the BPF 12 may be a combination of a high-pass filter (HPF) that blocks the DC component and allows a component of a frequency Of to pass, and a low-pass filter (LPF) that allows the component of the frequency Δf to pass and blocks a component of a frequency 2Δf. The beat component output from the BPF 12 is input to a second detector 13. The second detector 13 performs square detection on the input beat component and outputs a detection result of a frequency lower than a frequency of the beat component. Since the beat component input to the second detector 13 is a sinusoidal wave having a constant amplitude, a direct current voltage proportional to power of the beat component is output from the second detector 13. That is, the power of the signal that is the sum of the two beat components extracted by the BPF 12 is detected by the second detector 13, and the magnitude of the detected power is measured by a voltmeter 14. Phases of the beat components output from the first detector 11 are changed according to a phase of the 3-tone signal, and the two beat components of f₂−f₁ and f₃−f₂ interfere with each other because the frequencies thereof are equal to each other, so that the power of the beat component of the frequency Of is changed according to the phases of the beat components. By changing phase of any one or more tones of the 3-tone signal and measuring the change in power of the beat component of the frequency Of at that time by the second detector 13 and the voltmeter 14, a phase relationship (second-order differential value) of the 3 tones can be calculated using the calculation equation described below. By step-sweeping the frequency of the 3-tone signal, a phase characteristic in an arbitrary frequency range can be obtained.

Here, a method of extracting only the beat component of the frequency Of by the BPF 12 and inputting the beat component to the second detector 13 has been described, but the second-order differential value of the phase can be accurately calculated even when the DC component output from the first detector 11 and the beat component of the frequency 2Δf are input to the second detector 13 by particular calculation equation (described later) for calculating the second-order differential value of the phase. In this case, it is also possible to omit the BPF 12, or it is also possible to remove only the DC component and set the DC component input to the second detector 13 to zero by using the high-pass filter (HPF) instead of the BPF 12, or it is also possible to remove only the beat component of the frequency of 2Δf by using the low-pass filter (LPF) instead of the BPF 12. In a case where the BPF 12 is omitted and in a case where the HPF having a very low cutoff frequency is used instead of the BPF 12, the component of the frequency Of is not blocked even when the frequency Of is changed, and thus the frequency Of can be easily changed.

As the second detector 13, not only a detector that outputs a voltage proportional to the power of the input signal but also a detector that outputs a voltage proportional to the logarithm of the power of the input signal can be used. In a case where a logarithmic output detector is used, an output voltage of the detector is converted into input power of the detector by Equation (71). Here, Pin is the input power of the detector, Vₒᵤₜ is the output voltage of the detector, α is a sensitivity of the detector (unit: V/dB), and P_{interc} (logarithmic intercept) is the input power corresponding to zero output voltage.

$$[ Equation 71 ]$$

$${P}_{in} = {P}_{interc} {10}^{\frac{{V}_{out}}{10 α}} \qquad ( 71 )$$

It should be noted that, in the calculation equation described later, a value proportional to the power of the signal that has passed through the BPF 12 may be used, and the value proportional to the power may be calculated without performing the multiplication of P_{interc} in the above equation, in order to calculate a ratio of the power of the beat component.

### First Embodiment

FIGS. 2, 3, 4, 5, and 6 are diagrams showing a configuration of a phase characteristic measurement apparatus according to a first embodiment of the present invention. As shown in FIGS. 2 to 6, the phase characteristic measurement apparatus 1 of the first embodiment includes a first detector 11, a BPF 12, a second detector 13, a voltmeter 14, and a phase calculator 15.

Specifically, the first detector 11 receives a 3-tone signal obtained by combining three waves in a high-frequency band, and detects an instantaneous value of power of the 3-tone signal. The BPF 12 allows a frequency component of an angular frequency difference Δω (=ω₂−ω₁=ω₃−ω₂) between waves with adjacent frequencies of the 3-tone signal to pass and blocks a frequency component twice the angular frequency difference Δω and a direct current component, among signals output from the first detector 11. The first detector 11 is configured of, for example, a detector using a diode, and may have a characteristic capable of detecting a 3-tone signal obtained by combining three waves e₁, e₂, and e₃, and outputting a beat component of an angular frequency Δω. The second detector 13 detects power of the beat component that has passed through the BPF 12. The second detector 13 is configured of, for example, a detector using a diode, and may have a characteristic capable of detecting a tone spacing angular frequency Δω of the 3-tone signal. The voltmeter 14 measures a voltage of a signal output from the second detector 13. It is sufficient that the voltmeter 14 can measure a voltage corresponding to the output of the second detector 13, and for example, any one of an anode or a cathode of a detector using a diode is connected to one end of the voltmeter 14, and the other end is connected to a reference potential such as ground. In addition, when the reference potential is stable, the other end of the voltmeter 14 does not necessarily have to be ground. The phase calculator 15 calculates a phase relationship and calculates a phase characteristic, as will be described later. The voltmeter 14 in the drawings may be an ammeter. In addition, it is sufficient that the ammeter can measure a current corresponding to the output of the second detector 13, and for example, any one of an anode or a cathode of a detector using a diode is connected to one end of the ammeter. The other end of the ammeter may be connected to the reference potential, and a predetermined bias voltage may be applied to the diode. It should be noted that, in the calculation equation described later, in order to calculate a ratio of power of the beat component, a value proportional to power of a signal that has passed through the BPF 12 may be used, and in a case where the second detector 13 outputs a voltage or a current proportional to input power, the measured voltage value or current value may be used as it is.

Here, a method of generating the 3-tone signal input to the first detector 11 and a method of calculating a second-order differential value of a phase in the phase calculator 15 will be described. Five methods including one simple method that can be used in a case where all 3 tones have the equal amplitude and four methods that can be used even when the amplitudes of the 3 tones are unknown and are unequal amplitudes.

[1] Case where all 3 Tones have Equal Amplitude

First, a case where all 3 tones have the equal amplitude will be described with reference to FIG. 2. A 3-tone signal used for the first measurement is set as in the following Equation (72).

$$[ Equation 72 ]$$

$$\begin{matrix}{e}_{i} = cos ( {ω}_{i} t + {ϕ}_{i} ) , & i = 1 , 2 , 3\end{matrix} \qquad ( 72 )$$

A 3-tone signal used for the second measurement is set as in the following Equation (73).

$$[ Equation 73 ]$$

$$\begin{matrix}{e}_{i} = cos ( {ω}_{i} t + {ϕ}_{i} + {α}_{i} ) , & i = 1 , 2 , 3\end{matrix} \qquad ( 73 )$$

Here, t is a time, ωᵢ are angular frequencies of each tone, and φᵢ are phases of each tone. ωᵢ and φᵢ, where i=1, 2, 3 in Equation (72) are the same values as ωᵢ and φᵢ, where i=1, 2, 3 in Equation (73), respectively. The frequencies of each tone are equally spaced. That is, ωᵢ₊₁−ωᵢ=Δω, where i=1, 2 are established. In addition, each tone signal of the 3-tone signal used for the second measurement has known phase offsets αᵢ. The values of the phase offsets αᵢ of each tone are determined such that a second-order difference of the phase offsets of the three tone signals is φ_{α}. That is, the phase offsets are set so as to satisfy a relationship of Equation (74).

$$[ Equation 74 ]$$

$${ϕ}_{α} = {α}_{3} - 2 {α}_{2} + {α}_{1} \qquad ( 74 )$$

In order to satisfy this relationship, the phase offsets may be set for only one tone among the three tones, the phase offsets may be set for any two tones among the three tones, or the phase offsets may be set for all the three tones. In the 3-tone signal used for the first measurement, φ_{α}=0 is established because there is no phase offset.

When an intensity (power) of the 3-tone signal obtained by combining the 3-tone signals e₁, e₂, and e₃ is detected by the first detector 11, a signal proportional to (e₁+e₂+e₃)² is obtained. The signal includes the direct current component, the component of the angular frequency Δω, and the component of the angular frequency 2Δω, as described above.

Only the beat component having the angular frequency Δω is extracted from the signal by the BPF 12. When an operator that extracts only the angular frequency Ow component by the BPF 12 is defined as BPF_{Δω}[ ], the beat component (in a case where the second-order difference of the phase offsets is φ_{α}) extracted by the BPF 12 is represented as in the following Equation (75).

$$[ Equation 75 ]$$

$${BPF}_{Δω} [ {( {e}_{1} + {e}_{2} + {e}_{3} )}^{2} ] = {BPF}_{Δω} [ 2 {e}_{1} {e}_{2} + 2 {e}_{2} {e}_{3} ] = 2 cos ( \frac{{ϕ}_{3} - 2 {ϕ}_{2} + {ϕ}_{1} + {ϕ}_{α}}{2} ) cos ( Δω t + \frac{{ϕ}_{3} - {ϕ}_{1}}{2} + \frac{{α}_{3} - {α}_{1}}{2} ) \qquad ( 75 )$$

Therefore, when power E_{beat} (φ_{α}) of the beat component is detected by the second detector 13 and measured by the voltmeter 14, Equation (76) is established.

$$[ Equation 76 ]$$

$${E}_{beat} ( {ϕ}_{α} ) = 4 {cos}^{2} ( \frac{{ϕ}_{3} - 2 {ϕ}_{2} + {ϕ}_{1} + {ϕ}_{α}}{2} ) \qquad ( 76 )$$

Here, the beat power is measured while changing each tone signal such that the phase offsets establish α₃−2α₂+α₁=φ_{α}, 0. A ratio of the beat power E_{beat}(φ_{α}) in a case where the second-order difference of the phase offsets is φ_{α} (second measurement) to a beat power E_{beat} (0) in a case where the second-order difference of the phase offsets is 0 (first measurement) satisfies Equation (77).

$$[ Equation 77 ]$$

$$\begin{matrix}\frac{{E}_{beat} ( {ϕ}_{α} )}{{E}_{beat} ( 0 )} = {[ \frac{cos ( \frac{{ϕ}_{3} - 2 {ϕ}_{2} + {ϕ}_{1} + {ϕ}_{α}}{2} )}{cos ( \frac{{ϕ}_{3} - 2 {ϕ}_{2} + {ϕ}_{1}}{2} )} ]}^{2} \\ = {{[ cos ( \frac{{ϕ}_{α}}{2} ) - sin ( \frac{{ϕ}_{α}}{2} ) tan ( \frac{{ϕ}_{3} - 2 {ϕ}_{2} + {ϕ}_{1}}{2} ) ]}^{2}}^{2}\end{matrix} \qquad ( 77 )$$

Here, 0<φ_{α}<2π, −π≤φ₃−2φ₂+φ₁≤π are established.

Therefore, the second-order differential value of the phase at the angular frequency ω₂ can be expressed as Equation (78).

$$[ Equation 78 ]$$

$${ϕ}_{2}^{′′} = \frac{{d}^{2} ϕ}{d {ω}^{2}} {\vert}_{ω = {ω}_{2}} = \frac{{ϕ}_{3} - 2 {ϕ}_{2} + {ϕ}_{1}}{{Δω}^{2}} \qquad ( 78 )$$

Since a sign of cos(φ₃−2φ₂+φ₁)/2) is non-negative, in a case of classifying the positive and negative signs of (φ₃−2φ₂+φ₁+φ_{α})/2), Equation (79) is established.

$$[ Equation 79 ]$$

$$( 79 )$$

$${ϕ}_{2}^{′′} = \{ \begin{matrix}\frac{2}{{Δω}^{2}} {tan}^{- 1} ( \frac{\sqrt{\frac{{E}_{beat} ( {ϕ}_{α} )}{{E}_{beat} ( 0 )}} + cos ( \frac{{ϕ}_{α}}{2} )}{sin ( \frac{{ϕ}_{α}}{2} )} ) , & π - {ϕ}_{α} \leq {ϕ}_{3} - 2 {ϕ}_{2} + {ϕ}_{1} \leq π \\ \frac{2}{{Δω}^{2}} {tan}^{- 1} ( \frac{- \sqrt{\frac{{E}_{beat} ( {ϕ}_{α} )}{{E}_{beat} ( 0 )}} + cos ( \frac{{ϕ}_{α}}{2} )}{sin ( \frac{{ϕ}_{α}}{2} )} ) , & - π \leq {ϕ}_{3} - 2 {ϕ}_{2} + {ϕ}_{1} \leq π - {ϕ}_{α}\end{matrix}$$

A phase calculation method of Equation (79) is based on the division of E_{beat}(φ_{α})/E_{beat}(0), and the result does not change even when E_{beat}(φ_{α}) and E_{beat}(0) are multiplied by a constant, and thus E_{beat}(φ_{α}) and E_{beat}(0) may be values proportional to the power of the beat component extracted by the BPF 12. A phase measurement system is shown in FIG. 2.

Here, the sign of the argument in Equation (79) is indefinite. That is, it is difficult to determine the positive or negative of the sign in a measurement in which φ₃−2φ₂+φ₁ is in the vicinity of π−φ_{α} or ±π.

Therefore, it is necessary to use Equation (79) in a range of any of −π<φ₃−2φ₂+φ₁<π−φ_{α} or π−φ_{α}<φ₃−2φ₂+φ₁<π. A second-order difference φ_{β} of the phase offsets can be added separately from φ_{α} to shift the range of the measured value. That is, when phase offsets βᵢ in which β₃−2β₂+β₁=φ_{β} is established are added to the phases of each tone of the first measurement and the second measurement, the second-order difference of the phases establishes φ₂″Δω²+φ_{β}, and it is possible to avoid the vicinity of π−φ_{α} and the vicinity of ±π by selecting appropriate φ_{β}. In addition, it is also possible to avoid the vicinity of π−φ_{α} by adjusting φ_{α}. For example, it is desirable to set φ_{β} and φ_{α} such that an estimated value of φ₂″Δω²+φ_{β} is an intermediate value between π−φ_{α} and π or an intermediate value between −π and π−φ_{α}. In addition, since the measurement range of φ₂″Δω²+φ_{β} is from π−φ_{α} to π or from −π to π−φ_{α}, it is desirable to set Δω or φ_{α} according to the required measurement range.

When a non-zero φ_{β} is used, it is not limited to the second-order difference φ_{α}=0 of the phase offsets of the 3-tone signal used for the first measurement employed in this method.

This measurement method has an advantage that a phase measurement can be performed with two times of measurements. In this measurement method, the BPF 12 for extracting the angular frequency Δω component of the beat is necessary.

By sweeping the frequency of the 3-tone signal and obtaining the second-order differential value of the phase within a band to be measured using Equation (79) above, a frequency characteristic of the phase can be obtained by integrating the second-order differential value of the phase twice using the following Equation (80). The frequency characteristic of the phase is calculated by, for example, the phase calculator 15. θ₀ and θ₀′ of Equation (80) are initial phase and initial phase gradient, respectively, and are arbitrary integration constants.

$$[ Equation 80 ]$$

$${θ}_{N} = {\sum }_{j = 1}^{N} ( {\sum }_{j = 1}^{N} {ϕ}_{i}^{′′} Δω + {θ}_{0}^{′} ) Δω + {θ}_{0} \qquad ( 80 )$$

[2] Three Times Measurement Method in Case where Amplitude of 3-Tone is Unknown

Next, a case where the amplitudes of the 3-tone are unknown and are unequal amplitudes will be described. In the above description, a case is considered in which the amplitudes of the tone signals are all equal to each other, but in reality, there is a frequency characteristic of the amplitude, and the amplitudes of each tone signal are unknown and are unequal amplitudes. Here, the measurement is performed three times while changing the phase of the 3-tone signal.

The first-time 3-tone signal is set as in the following Equation (81).

$$[ Equation 81 ]$$

$$\begin{matrix}{e}_{i} = {a}_{i} cos ( {ω}_{i} t + {ϕ}_{i} ) , & i = 1 , 2 , 3\end{matrix} \qquad ( 81 )$$

(Here, aᵢ represent amplitudes, ωᵢ represent angular frequencies, φᵢ represent phases, t represents a time, and ω₂−ω₁=ω₃−ω₂=Δω is established. The same applies hereinafter.)

The second-time 3-tone signal is set as in the following Equation (82).

$$[ Equation 82 ]$$

$${e}_{i} = \begin{matrix}{a}_{i} cos ( {ω}_{i} t + {ϕ}_{i} + {α}_{1 i} ) , & i = 1 , 2 , 3\end{matrix} \qquad ( 82 )$$

Each tone signal has known phase offsets α₁ᵢ. The values of the phase offsets α₁ᵢ of each tone are determined such that the second-order difference of the phase offsets of the three tone signals is φ_{α1}. That is, the phase offsets are set so as to satisfy a relationship of φ_{α1}=α₁₃−2α₁₂+α₁₁.

The third-time 3-tone signal is set as in the following Equation (83).

$$[ Equation 83 ]$$

$${e}_{i} = \begin{matrix}{a}_{i} cos ( {ω}_{i} t + {ϕ}_{i} + {α}_{2 i} ) , & i = 1 , 2 , 3\end{matrix} \qquad ( 83 )$$

Each tone signal has known phase offsets α₂₁. The values of the phase offsets α₂₁ of each tone are determined such that the second-order difference of the phase offsets of the three tone signals is φ_{α2}. That is, the phase offsets are set so as to satisfy a relationship of φ_{α2}=α₂₃−2α₂₂+α₂₁. In order to satisfy these relationships, the phase offsets may be set for only one tone among the three tones, the phase offsets may be set for any two tones among the three tones, or the phase offsets may be set for all three tones. In the 3-tone signal used for the first measurement, φ_{α}=0 is established because there is no phase offset. αᵢ, ωᵢ and φᵢ, where i=1, 2, 3 in Equation (81), Equation (82), and Equation (83) are the same values, respectively.

Power of an angular frequency Δω component BPF_{Δω}[(e₁+e₂+e₃)²] of the beat of these 3-tone signals (in a case where the second-order difference of the phase offsets is φ_{α}) is defined as E_{beat}(φ_{α}). When φ_{α1}=π/2+Δφ_{α1}+φ_{α2} and φ_{α2}=π+2Δφ_{α2} are established, powers E_{beat}(0), E_{beat}(φ_{α1}), and E_{beat}(φ_{α2}) of the angular frequency Δω components of the beat of the first, second, and third-time 3-tone signals are as in the following Equation (84).

$$[ Equation 84 ]$$

$${E}_{beat} ( 0 ) = 2 {a}_{1} {a}_{2}^{2} {a}_{3} \{ cos ( {ϕ}_{3} - 2 {ϕ}_{2} + {ϕ}_{1} + {Δϕ}_{α 2} ) cos ( {Δϕ}_{α 2} ) + sin ( {ϕ}_{3} - 2 {ϕ}_{2} + {ϕ}_{1} + {Δϕ}_{α 2} ) sin ( {Δϕ}_{α 2} ) \} + {a}_{1}^{2} {a}_{2}^{2} + {a}_{2}^{2} {a}_{3}^{2} \qquad ( 84 )$$

$${E}_{beat} ( {ϕ}_{α 1} ) = 2 {a}_{1} {a}_{2}^{2} {a}_{3} \{ - sin ( {ϕ}_{3} - 2 {ϕ}_{2} + {ϕ}_{1} + {Δϕ}_{α 2} ) cos ( {Δϕ}_{α 1} ) - cos ( {ϕ}_{3} - 2 {ϕ}_{2} + {ϕ}_{1} + {Δϕ}_{α 2} ) sin ( {Δϕ}_{α 1} ) \} + {a}_{1}^{2} {a}_{2}^{2} + {a}_{2}^{2} {a}_{3}^{2}$$

$${E}_{beat} ( {ϕ}_{α 2} ) = 2 {a}_{1} {a}_{2}^{2} {a}_{3} \{ - cos ( {ϕ}_{3} - 2 {ϕ}_{2} + {ϕ}_{1} + {Δϕ}_{α 2} ) cos ( {Δϕ}_{α 2} ) + sin ( {ϕ}_{3} - 2 {ϕ}_{2} + {ϕ}_{1} + {Δϕ}_{α 2} ) sin ( {Δϕ}_{α 2} ) \} + {a}_{1}^{2} {a}_{2}^{2} + {a}_{2}^{2} {a}_{3}^{2}$$

From this result, the second-order differential value of the phase is expressed as Equation (85).

$$[ Equation 85 ]$$

$${ϕ}_{2}^{″} = \frac{1}{Δ {ω}^{2}} ( {tan}^{- 1} ( \frac{cos ( Δ {ϕ}_{α} \text{?} )}{cos ( Δ {ϕ}_{α} \text{?} ) + sin ( Δ {ϕ}_{α} \text{?} )} ( \frac{{E}_{beat} ( 0 ) - 2 {E}_{beat} ( {ϕ}_{α} \text{?} ) + {E}_{beat} ( {ϕ}_{α} \text{?} )}{{E}_{beat} ( 0 ) - {E}_{beat} ( {ϕ}_{α} \text{?} )} - \frac{sin ( Δ {ϕ}_{α} \text{?} )}{cos ( Δ {ϕ}_{α} \text{?} )} ) ) - Δ {ϕ}_{α} \text{?} ) \qquad ( 85 )$$

$$\text{?} \text{indicates text missing or illegible when filed}$$

In addition, when the a tan 2 function is used, Equation (86) is established, and

$$[ Equation 86 ]$$

$${ϕ}_{2}^{″} = \frac{1}{Δ {ω}^{2}} ( atan 2 ( \frac{cos ( Δ {ϕ}_{α 2} )}{cos ( Δ {ϕ}_{α 1} ) + sin ( Δ {ϕ}_{α 2} )} ( cos ( Δ {ϕ}_{α 2} ) ( {E}_{beat} ( 0 ) - 2 {E}_{beat} ( {ϕ}_{α 1} ) + {E}_{beat} ( {ϕ}_{α 2} ) ) - sin ( Δ {ϕ}_{α 1} ) ( {E}_{beat} ( 0 ) - {E}_{beat} ( {ϕ}_{α 2} ) ) ) , cos ( Δ {ϕ}_{α 2} ) ( {E}_{beat} ( 0 ) - {E}_{beat} ( {ϕ}_{α 2} ) ) ) - Δ {ϕ}_{α 2} ) \qquad ( 86 )$$

a phase measurement is possible within a range of φ₂″Δω² of 2π. Therefore, the measurement range does not change even when arbitrary φ_{α1} and φ_{α2} are taken. However, it is desirable to avoid the vicinity of φ₃−2φ₂+φ₁=0 because peaks of each tone overlap each other and a peak factor increases in the first measurement. A second-order difference φ_{β} of the phase offsets can be added separately from φ_{α} to shift the second-order difference of the phases. That is, when the phase offsets βᵢ at which β₃−2β₂+β₁=φ_{β} is established are added to the phases of each tone of each measurement, the measured value of the second-order difference of the phase is φ₂″Δω²+φ_{β}, and thus it is possible to avoid the vicinity of φ₂″Δω²+φ_{β}=0 by selecting appropriate φ_{α}. By providing more appropriate φ_{α1} and φ_{α2}, the peak factor is suppressed (average power is increased under peak power limit), and the S/N may be improved by adjusting the peaks of each tone not to overlap each other in the second and third measurements (such that φ₂″Δω²+φ_{β}+φ_{α1} or φ₂″Δω²+φ_{β}+φ_{α2} is not close to zero).

When a non-zero φ_{β} is used, it is not limited to the second-order difference φ_{α}=0 of the phase offsets of the 3-tone signal used for the first measurement employed in this method.

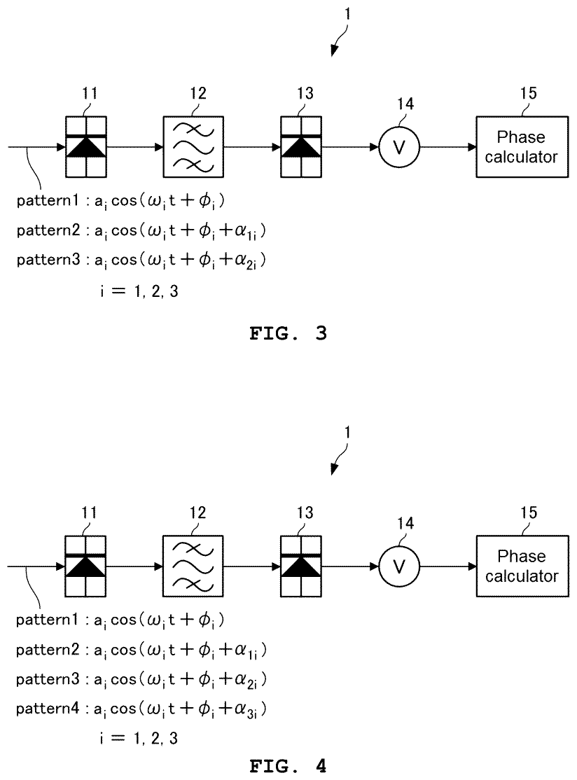

Similarly to the previous section, the frequency characteristic of the phase can be calculated by sweeping the frequency of the 3-tone signal and integrating the second-order differential value of the phase twice using Equation (80). A phase measurement system is shown in FIG. 3.

The component of the angular frequency 2Δω output from the first detector 11 is a beat of two tone signals of e₁ and e₃, and the magnitude of the beat is constant regardless of the phase of each tone. The DC component output from the first detector 11 is also constant regardless of the phase of each tone. Therefore, even when the component of 2Δω and the DC component are present in the measurement of the beat power of each tone by the second detector 13 (even when the component of DC or 2Δω is present in addition to that of Δω in E_{beat}), the component of 2Δω and the DC component in E_{beat}(0)−2E_{beat}(φ_{α1})+E_{beat}(φ_{α2}) and E_{beat}(0)−E_{beat}(φ_{α2}) in Equation (85) and Equation (86) are subtracted to be zero, and thus there is no contribution to the measurement result. Therefore, the BPF 12 for extracting the angular frequency Lw component of the beat is not necessary. However, it is desirable to use the BPF 12 in order to improve the S/N. Similarly, there is also an effect of removing a direct current offset during the E_{beat} measurement. In addition, the phase calculation method of Equation (85) and Equation (86) is based on a ratio of E_{beat}(0)−2E_{beat}(φ_{α1})+E_{beat}(φ_{α2}) and E_{beat}(0)−E_{beat}(φ_{α2}), and since the result does not change even when E_{beat}(φ_{α}) is multiplied by a constant, E_{beat}(φ_{α}) may be a value proportional to the power of the signal output from the first detector 11.

### Definition of a tan 2 Function

a tan 2(y, x) is a function that returns a polar angle of a point (x, y) in a rectangular coordinate system. The possible value range is −π<a tan 2≤π.

[3] Four Times Measurement Method in which Each Tone has Arbitrary Amplitude

In addition to the 3-tone signal in the previous section, a fourth-time 3-tone signal is defined as follows.

$$[ Equation 87 ]$$

$${e}_{i} = {a}_{i} cos ( {ω}_{i} t + {ϕ}_{i} + {α}_{3 i} ) , i = 1 , 2 , 3 \qquad ( 87 )$$

(Here, αᵢ represent amplitudes, ωᵢ represent angular frequencies, φᵢ represent phases, t represents a time, and ω₂−ω₁=ω₃−ω₂=Δω is established.) Each tone signal has known phase offsets α₃ᵢ. The values of the phase offsets α₃ᵢ of each tone are determined such that the second-order difference of the phase offsets of the three tone signals is φ_{α3}. That is, the phase offsets are set so as to satisfy a relationship of φ_{α3}=α₃₃−2α₃₂+α₃₁. In order to satisfy this relationship, the phase offsets may be set for only one tone among the three tones, the phase offsets may be set for any two tones among the three tones, or the phase offsets may be set for all the three tones. In the 3-tone signal used for the first measurement, φ_{α}=0 is established because there is no phase offset. αᵢ, ωᵢ and φᵢ, where i=1, 2, 3 in Equation (81), Equation (82), Equation (83), and Equation (87) are the same values, respectively.

When φ_{α1}=π/2+Δφ_{α1}+Δφ_{α2}, φ_{α2}=π+2Δφ_{α2}, and φ_{α3}=3π/2+Δφ_{α3}+Δφ_{α2} are established, the powers E_{beat}(0), E_{beat} (φ_{α1}), E_{beat} (φ_{α2}), and E_{beat} (φ_{α3}) of the angular frequency Δω component of the beat of each measurement are calculated according to the following equation as in the previous section.

$$[ Equation 88 ]$$

$${E}_{beat} ( 0 ) = 2 {a}_{1} {a}_{2}^{2} {a}_{3} \{ cos ( {ϕ}_{3} - 2 {ϕ}_{2} + {ϕ}_{1} + Δ {ϕ}_{α 2} ) cos ( Δ {ϕ}_{α 2} ) + sin ( {ϕ}_{3} - 2 {ϕ}_{2} + {ϕ}_{1} + Δ {ϕ}_{α 2} ) sin ( Δ {ϕ}_{α 2} ) \} + {a}_{1}^{2} {a}_{2}^{2} + {a}_{2}^{2} {a}_{3}^{2} \qquad ( 88 )$$

$${E}_{beat} ( {ϕ}_{α1} ) = 2 {a}_{1} {a}_{2}^{2} {a}_{3} \{ - sin ( {ϕ}_{3} - 2 {ϕ}_{2} + {ϕ}_{1} + Δ {ϕ}_{α 2} ) cos ( Δ {ϕ}_{α 1} ) - cos ( {ϕ}_{3} - 2 {ϕ}_{2} + {ϕ}_{1} + Δ {ϕ}_{α 2} ) sin ( Δ {ϕ}_{α 1} ) \} + {a}_{1}^{2} {a}_{2}^{2} + {a}_{2}^{2} {a}_{3}^{2}$$

$${E}_{beat} ( {ϕ}_{α2} ) = 2 {a}_{1} {a}_{2}^{2} {a}_{3} \{ - cos ( {ϕ}_{3} - 2 {ϕ}_{2} + {ϕ}_{1} + Δ {ϕ}_{α 2} ) cos ( Δ {ϕ}_{α 2} ) + sin ( {ϕ}_{3} - 2 {ϕ}_{2} + {ϕ}_{1} + Δ {ϕ}_{α 2} ) sin ( Δ {ϕ}_{α 2} ) \} + {a}_{1}^{2} {a}_{2}^{2} + {a}_{2}^{2} {a}_{3}^{2}$$

$${E}_{beat} ( {ϕ}_{α3} ) = 2 {a}_{1} {a}_{2}^{2} {a}_{3} \{ sin ( {ϕ}_{3} - 2 {ϕ}_{2} + {ϕ}_{1} + Δ {ϕ}_{α 2} ) cos ( Δ {ϕ}_{α 3} ) + cos ( {ϕ}_{3} - 2 {ϕ}_{2} + {ϕ}_{1} + Δ {ϕ}_{α 2} ) sin ( Δ {ϕ}_{α 3} ) \} + {a}_{1}^{2} {a}_{2}^{2} + {a}_{2}^{2} {a}_{3}^{2}$$

From this result, the second-order differential value of the phase is expressed as Equation (89).

$$[ Equation 89 ]$$

$${ϕ}_{2}^{″} = \frac{1}{Δ {ω}^{2}} ( {tan}^{- 1} ( \frac{2 cos ( Δ {ϕ}_{α} \text{?} )}{cos ( Δ {ϕ}_{α} \text{?} ) + cos ( Δ {ϕ}_{α} \text{?} )} ( \frac{{E}_{beat} ( {ϕ}_{α} \text{?} ) - {E}_{beat} ( {ϕ}_{α} \text{?} )}{{E}_{beat} ( 0 ) - {E}_{beat} ( {ϕ}_{α} \text{?} )} - \frac{sin ( Δ {ϕ}_{α} \text{?} ) + sin ( Δ {ϕ}_{α} \text{?} )}{2 cos ( Δ {ϕ}_{α} \text{?} )} ) ) - Δ {ϕ}_{α} \text{?} ) \qquad ( 89 )$$

$$\text{?} \text{indicates text missing or illegible when filed}$$

In addition, when the a tan 2 function is used, the function is expressed as the following equation.

$$[ Equation 90 ]$$

$${ϕ}_{2}^{″} = \frac{1}{Δ {ω}^{2}} ( atan 2 ( \frac{2 cos ( Δ {ϕ}_{α} \text{?} )}{cos ( Δ {ϕ}_{α} \text{?} ) + cos ( Δ {ϕ}_{α} \text{?} )} ( 2 cos ( Δ {ϕ}_{α} \text{?} ) ( {E}_{beat} ( {ϕ}_{α} \text{?} ) - {E}_{beat} ( {ϕ}_{α} \text{?} ) ) - ( sin ( Δ {ϕ}_{α} \text{?} ) + sin ( Δ {ϕ}_{α} \text{?} ) ) ( {E}_{beat} ( 0 ) - {E}_{beat} ( {ϕ}_{α} \text{?} ) ) ) , 2 cos ( Δ {ϕ}_{α} \text{?} ) ( {E}_{beat} ( 0 ) - {E}_{beat} ( {ϕ}_{α} \text{?} ) ) ) - Δ {ϕ}_{α} \text{?} ) \qquad ( 90 )$$

$$\text{?} \text{indicates text missing or illegible when filed}$$

It is possible to perform a phase measurement within a range of φ₂″Δω² of 2π. Therefore, the measurement range does not change even when arbitrary φ_{α1}, φ_{α2}, and φ_{α3} are taken. However, it is desirable to avoid the vicinity of φ₃−2φ₂+φ₁=0 because peaks of each tone overlap each other and a peak factor increases in the first measurement. A second-order difference φ_{β} of the phase offsets can be added separately from φ_{α} to shift the second-order difference of the phase. That is, when the phase offsets βᵢ at which β₃−2β₂+β₁=φ_{β} is established are added to the phases of each tone of each measurement, the second-order difference of the phase is φ₂″Δω²+φ_{β}, and thus it is possible to avoid the vicinity of φ₂″Δω²+φ_{β}=0 by selecting appropriate φ_{β}. By providing more appropriate φ_{α1}, φ_{α2}, and φ_{α3}, the peak factor is suppressed (by increasing average power under peak power limit), and the S/N may be improved by adjusting the peaks of each tone not to overlap each other in the second, third, and fourth-time measurements (such that φ₂″Δω²+φ_{β}+φ_{α1}, φ₂″Δω²+φ_{β}+φ_{α2}, and φ₂″Δω²+φ_{β}+φ_{α3} are not close to zero).

When a non-zero φ_{β} is used, it is not limited to the second-order difference φ_{α}=0 of the phase offsets of the 3-tone signal used for the first measurement employed in this method.

Similarly to the previous section, the frequency characteristic of the phase can be calculated by sweeping the frequency of the 3-tone signal and integrating the second-order differential value of the phase twice using Equation (80). A phase measurement system is shown in FIG. 4.

The component of the angular frequency 2Δω output from the first detector 11 is a beat of two tone signals of e₁ and e₃, and the magnitude of the beat is constant regardless of the phase of each tone. The DC component output from the first detector 11 is also constant regardless of the phase of each tone. Therefore, even when the component of 2Δω and the DC component are present in the measurement of the beat power of each tone by the second detector 13 (even when the component of DC or 2Δω is present in addition to that of Δω in E_{beat}), the component of 2Δω and the DC component in E_{beat}(φ_{α3})−E_{beat}(φ_{α1}) and E_{beat}(0)−E_{beat}(φ_{α2}) in Equation (89) and Equation (90) are subtracted to be zero, and thus there is no contribution to the measurement result. Therefore, the BPF 12 for extracting the angular frequency Δω component of the beat is not necessary. However, it is desirable to use the BPF 12 in order to improve the S/N. Similarly, there is also an effect of removing a direct current offset during the E_{beat} measurement. In addition, the phase calculation method of Equation (89) and Equation (90) is based on a ratio of E_{beat}(φ_{α3})−E_{beat}(φ_{α1}) and E_{beat}(0)−E_{beat}(φ_{α2}), and since the result does not change even when E_{beat}(φ_{α}) is multiplied by a constant, E_{beat}(φ_{α}) may be a value proportional to the power of the signal output from the first detector 11.

### [4] Each Tone Arbitrary Amplitude, 2-Tone Measurement Combined, and Four Times Measurement Method

In a case where the amplitudes of each tone signal are arbitrary and unknown, the offset component in a case of the 3-tone measurement can be measured to obtain the phase by measuring the beat power in a case where one tone among the three tones is zero.

In the first measurement, the power of the beat is measured with the third tone signal set to zero as shown in the following Equation (91).

$$[ Equation 91 ]$$

$${e}_{i} = {a}_{i} cos ( {ω}_{i} t + {ϕ}_{i} + {γ}_{i} ) , i = 1 , 2 \qquad ( 91 )$$

(Here, aᵢ represent amplitudes, ωᵢ represent angular frequencies, φᵢ represent phases, γᵢ represent arbitrary phases, t represents a time, and ω₂−ω₁=ω₃−ω₂=Δω is established. The same applies hereinafter.)

The power of the beat is expressed as Equation (92).

$$[ Equation 92 ]$$

$${E}_{beat} ( {a}_{3} = 0 ) = {a}_{1}^{2} {a}_{2}^{2} \qquad ( 92 )$$

Similarly, in the second measurement, the power of the beat is measured with the first tone signal set to zero as shown in the following Equation (93).

$$[ Equation 93 ]$$

$${e}_{i} = {a}_{i} cos ( {ω}_{i} t + {ϕ}_{i} + {γ}_{i} ) , i = 2 , 3 \qquad ( 93 )$$

The power of the beat is expressed as Equation (94).

$$[ Equation 94 ]$$

$${E}_{beat} ( {a}_{1} = 0 ) = {a}_{2}^{2} {a}_{3}^{2} \qquad ( 94 )$$

In the first measurement and the second measurement, a beat of the angular frequency Δω is generated due to the 2-tone signal of the angular frequency spacing Δω, and the power of the beat is irrelevant to the phase of each tone. Therefore, γᵢ may be arbitrary phases.

When the 3-tone signal used for the third measurement is expressed as Equation (95),

$$[ Equation 95 ]$$

$${e}_{i} = {a}_{i} cos ( {ω}_{i} t + {ϕ}_{i} ) , i = 1 , 2 , 3 \qquad ( 95 )$$

the power of the angular frequency Δω component of the beat is expressed as Equation (96).

$$[ Equation 96 ]$$

$${E}_{beat} ( 0 ) = 2 {a}_{1} {a}_{2}^{2} {a}_{3} cos ( {ϕ}_{3} - 2 {ϕ}_{2} + {ϕ}_{1} ) + {a}_{1}^{2} {a}_{2}^{2} + {a}_{2}^{2} {a}_{2}^{2} = 2 {a}_{1} {a}_{2}^{2} {a}_{3} cos ( {ϕ}_{3} - 2 {ϕ}_{2} + {ϕ}_{1} ) + {E}_{beat} ( {a}_{3} = 0 ) + {E}_{beat} ( {a}_{1} = 0 ) \qquad ( 96 )$$

The 3-tone signal used for the fourth measurement is set as in the following Equation (97).

$$[ Equation 97 ]$$

$${e}_{i} = {a}_{i} cos ( {ω}_{i} t + {ϕ}_{i} + {α}_{1 i} ) , i = 1 , 2 , 3 \qquad ( 97 )$$

Each tone signal has known phase offsets α₁ᵢ. The values of the phase offsets α₁ᵢ of each tone are determined such that the second-order difference of the phase offsets of the three tone signals is φ_{α1}. That is, the phase offsets are set so as to satisfy a relationship of φ_{α1}=α₁₃−2α₁₂+α₁₁. In order to satisfy this relationship, the phase offsets may be set for only one tone among the three tones, the phase offsets may be set for any two tones among the three tones, or the phase offsets may be set for all the three tones. In the 3-tone signal used for the third measurement, φ_{α}=0 is established because there is no phase offset. αᵢ, ωᵢ and φᵢ, where i=1, 2, 3 in Equation (91), Equation (93), Equation (95), and Equation (97) are the same values, respectively. The power of the angular frequency Δω component of the beat in the fourth measurement is expressed as Equation (98).

$$[ Equation 98 ]$$

$${E}_{beat} ( {ϕ}_{α1} ) = 2 {a}_{1} {a}_{2}^{2} {a}_{3} \{ cos ( {ϕ}_{3} - 2 {ϕ}_{2} + {ϕ}_{1} ) cos ( Π / 2 + Δ {ϕ}_{α 1} ) - sin ( {ϕ}_{3} - 2 {ϕ}_{2} + {ϕ}_{1} ) sin ( Π / 2 + Δ {ϕ}_{α1} ) \} + {a}_{1}^{2} {a}_{2}^{2} + {a}_{2}^{2} {a}_{3}^{2} = - 2 {a}_{1} {a}_{2}^{2} {a}_{3} ( sin ( {ϕ}_{3} - 2 {ϕ}_{2} + {ϕ}_{1} ) cos ( Δ {ϕ}_{α 1} ) + cos ( {ϕ}_{3} - 2 {ϕ}_{2} + {ϕ}_{1} ) sin ( Δ {ϕ}_{α 1} ) \} + {E}_{beat} ( {a}_{3} = 0 ) + {E}_{beat} ( {a}_{1} = 0 ) \qquad ( 98 )$$

Here, φ_{α1}=π/2+Δφ_{α1} is established.

The second-order differential value of the phase is expressed as Equation (99).

$$[ Equation 99 ]$$

$${ϕ}_{2}^{″} = \frac{1}{{Δω}^{2}} {tan}^{- 1} ( \frac{1}{cos ( Δ {ϕ}_{α} \text{?} )} ( - \frac{{E}_{beat} ( {ϕ}_{α} \text{?} ) - {E}_{beat} ( a \text{?} = 0 ) - {E}_{beat} ( a \text{?} = 0 )}{{E}_{beat} ( 0 ) - {E}_{beat} ( a \text{?} = 0 ) - {E}_{beat} ( a \text{?} = 0 )} - sin ( Δ {ϕ}_{α} \text{?} ) ) ) \qquad ( 99 )$$

$$\text{?} \text{indicates text missing or illegible when filed}$$

In addition, when the a tan 2 function is used, Equation (100) is established, and

$$[ Equation 100 ]$$

$${ϕ}_{2}^{′′} = \frac{1}{{Δω}^{2}} atan 2 ( \frac{1}{cos ( {Δϕ}_{α 3} )} ( - {E}_{beat} ( {ϕ}_{α 1} ) + {E}_{beat} ( {a}_{3} = 0 ) + {E}_{beat} ( {a}_{1} = 0 ) - sin ( {Δϕ}_{α 1} ) ( {E}_{beat} ( 0 ) - {E}_{beat} ( {a}_{3} = 0 ) - {E}_{beat} ( {a}_{1} = 0 ) ) ) , {E}_{beat} ( 0 ) - {E}_{beat} ( {a}_{3} = 0 ) - {E}_{beat} ( {a}_{1} = 0 ) ) \qquad ( 100 )$$

a phase measurement is possible within a range of φ₂″Δω² of 2π. Therefore, the measurement range does not change even when arbitrary φ_{α1} is taken. However, it is desirable to avoid the vicinity of φ₃−2φ₂+φ₁=0 because peaks of each tone overlap each other and a peak factor increases in the third measurement. A second-order difference φ_{β} of the phase offset can be added separately from φ_{α} to shift the second-order difference of the phase. That is, when the phase offsets βᵢ at which β₃−2β₂+β₁=φ_{β} is established are added to the phases of each tone of the third and fourth measurements, the second-order difference of the phase is φ₂″Δω²+φ_{β}, and thus it is possible to avoid the vicinity of φ₂″Δω²+φ_{β}=0 by selecting appropriate φ_{β}. By providing more appropriate φ_{α1}, the peak factor is suppressed (by increasing average power under peak power limit), and the S/N may be improved by adjusting the peak of each tone not to overlap each other in the fourth measurement (such that φ₂″Δω²+φ_{β}+φ_{α1} is not close to zero).

When a non-zero φ_{β} is used, it is not limited to the second-order difference φ_{α}=0 of the phase offsets of the 3-tone signal used for the third measurement employed in this method.

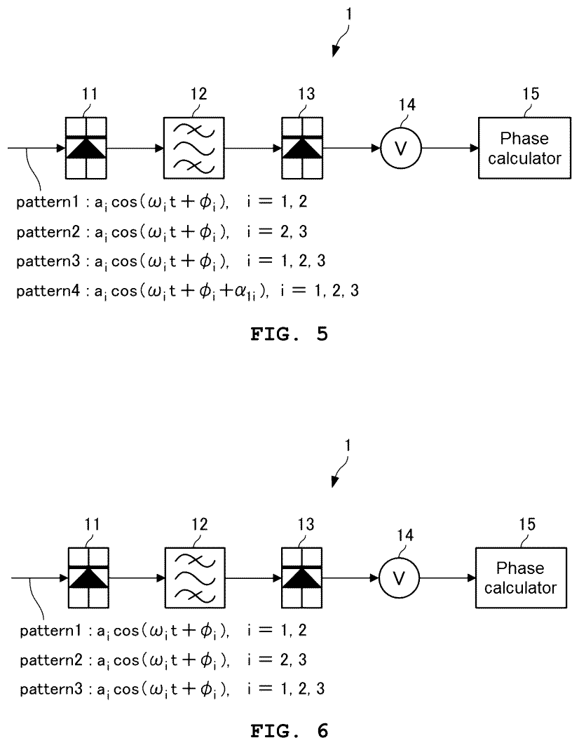

Similarly to the previous section, the frequency characteristic of the phase can be calculated by sweeping the frequencies of the 2-tone and 3-tone signals and integrating the second-order differential value of the phase twice by Equation (80). A phase measurement system is shown in FIG. 5.

In this example, the BPF 12 for extracting the angular frequency Δω component of the beat is necessary. In addition, the phase calculation method of Equation (99) and Equation (100) is based on a ratio of E_{beat}(φ_{α1})−E_{beat}(a₃=0)−E_{beat}(a₁=0) and E_{beat}(0)−E_{beat}(a₃=0)−E_{beat}(a₁=0), and the result does not change even when E_{beat}(φ_{α}), E_{beat}(0), E_{beat}(a₃=0), and E_{beat}(a₁=0) are multiplied by a constant, and thus E_{beat}(φ_{α}), E_{beat}(0), E_{beat}(a₃=0), and E_{beat}(a₁=0) may be values proportional to the power of the signal output from the BPF 12.

### [5] Each Tone Arbitrary Amplitude, 2-Tone Measurement Combined, and Three Times Measurement Method

It is possible to measure the phase characteristic only by the two times of 2-tone measurement and the one time of 3-tone measurement in the previous section.

The 2-tone signal used for the first measurement is set as in the following Equation (101).

$$[ Equation 101 ]$$

$${e}_{i} = {a}_{i} cos ( {ω}_{i} t + {ϕ}_{i} + {γ}_{i} ) , i = 1 , 2 \qquad ( 101 )$$

(Here, aᵢ represent amplitudes, ωᵢ represent angular frequencies, φᵢ represent phases, γᵢ represent arbitrary phases, t represents a time, and ω₂−ω₁=ω₃−ω₂=Δω is established. The same applies hereinafter.)

The 2-tone signal used for the second measurement is set as in the following Equation (102).

$$[ Equation 102 ]$$

$${e}_{i} = {a}_{i} cos ( {ω}_{i} t + {ϕ}_{i} + {γ}_{i} ) , i = 2 , 3 \qquad ( 102 )$$

In the first measurement and the second measurement, a beat of the angular frequency Δω is generated due to the 2-tone signal of the angular frequency spacing Δω, and the power of the beat is irrelevant to the phase of each tone. Therefore, γᵢ may be arbitrary phases.

The 3-tone signal used for the third measurement is set as in the following Equation (103).

$$[ Equation 103 ]$$

$${e}_{i} = {a}_{i} cos ( {ω}_{i} t + {ϕ}_{i} ) , i = 1 , 2 , 3 \qquad ( 103 )$$

aᵢ, ωᵢ and φᵢ, where i=1, 2, 3 in Equation (101), Equation (102), and Equation (103) are the same values, respectively. The power of the angular frequency Lw component of the beat in the first, second, and third measurements is represented by Equation (92), Equation (94), and Equation (96), respectively. Therefore, the second-order differential value of the phase can be calculated by Equation (104).

$$[ Equation 104 ]$$

$${ϕ}_{2}^{′′} = \frac{1}{{Δω}^{2}} {cos}^{- 1} ( \frac{{E}_{beat} ( 0 ) - {E}_{beat} ( {a}_{3} = 0 ) - {E}_{beat} ( {a}_{1} = 0 )}{2 \sqrt{{E}_{beat} ( {a}_{1} = 0 ) {E}_{beat} ( {a}_{3} = 0 )}} ) \qquad ( 104 )$$

However, since the measurement range is 0<φ₃−2φ₂+φ₁<π, it is necessary to avoid the vicinity of φ₂″Δω²=0 and π. When a second-order difference φ_{β} of the phase offsets is set and the phase offsets βᵢ at which β₃−2β₂+β₁=φ_{β} is established are added to the phases of each tone of the third measurement, the second-order difference of the phase is φ₂″Δω²+φ_{β}, and it is possible to avoid the vicinity of 0 and n by selecting appropriate pp.

In addition, by adjusting φ₂″Δω²+φ_{β} not to approach zero, the peaks of each tone can be prevented from overlapping each other in the third measurement, and the peak factor is suppressed (by increasing average power under peak power limit), which may improve the S/N.

When a non-zero φ_{β} is used, it is not limited to the second-order difference φ_{α}=0 of the phase offsets of the 3-tone signal used for the third measurement employed in this method.

Similarly to the previous section, the frequency characteristic of the phase can be calculated by sweeping the frequencies of the 2-tone and 3-tone signals and integrating the second-order differential value of the phase twice by Equation (80). A phase measurement system is shown in FIG. 6. This measurement method has an advantage that a phase measurement can be performed with three measurements as compared with the previous section.

In this example, the BPF 12 for extracting the angular frequency Δω component of the beat is necessary. In addition, the phase calculation method of Equation (104) is based on a ratio of E_{beat}(0)−E_{beat}(a₃=0)−E_{beat}(a₁=0) and √(E_{beat}(a₁=0)E_{beat}(a₃=0), and since the result does not change even when E_{beat}(0), E_{beat}(a₃=0), and E_{beat}(a₁=0) are multiplied by a constant, E_{beat}(0), E_{beat}(a₃=0), and E_{beat}(a₁=0) may be values proportional to the power of the signal output from the BPF 12.

The phase characteristic measurement technology presented in the present specification can be applied not only to an apparatus that measures a phase characteristic but also to a signal generator (SG) or a signal analyzer (SA) that incorporates the apparatus.

As a result, it is expected that the quality of modulation and demodulation of a wideband signal is improved.

### Second Embodiment

Next, a signal generator including a phase characteristic measurement apparatus will be described.

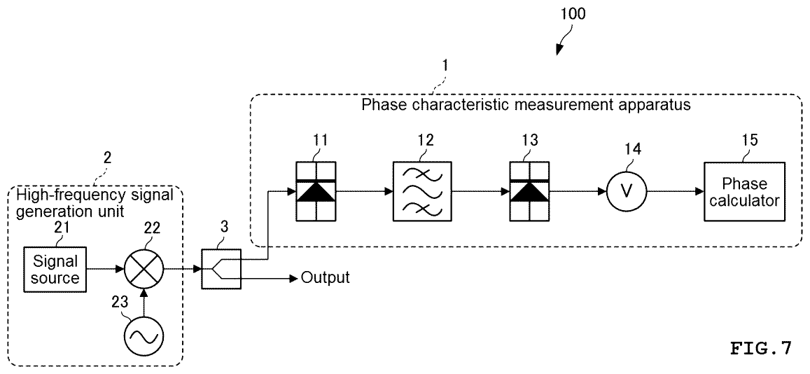

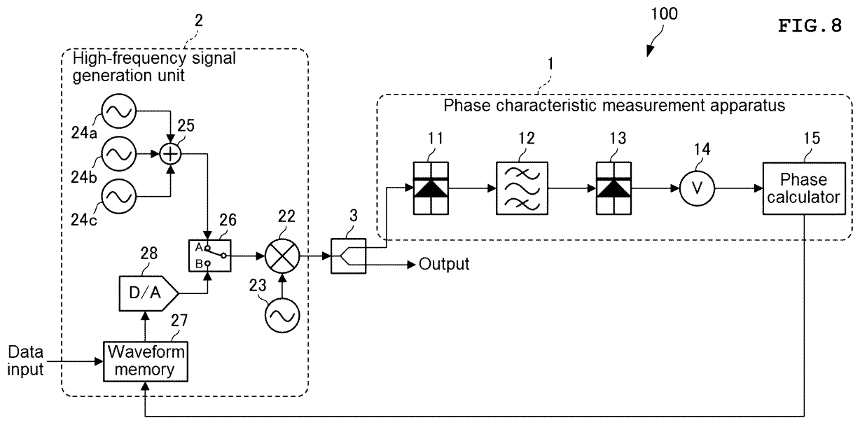

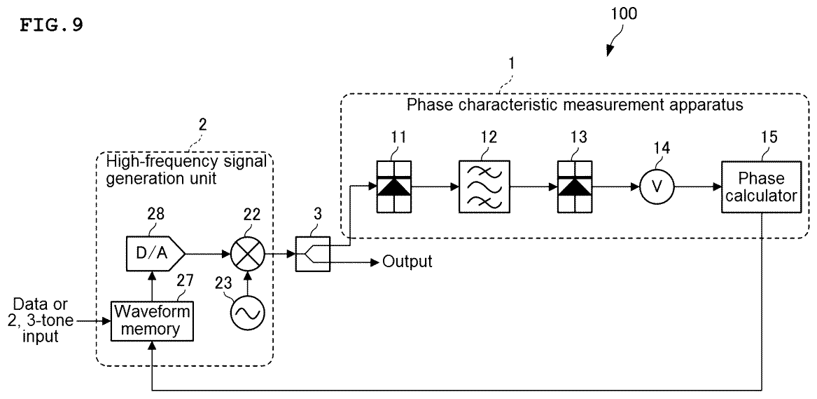

FIG. 7 shows a schematic configuration of a signal generator 100 provided with the phase characteristic measurement apparatus 1, FIG. 8 shows a detailed configuration of the signal generator 100, and FIG. 9 shows another detailed configuration of the signal generator 100. As shown in FIGS. 7, 8, and 9, the signal generator 100 includes the phase characteristic measurement apparatus 1, a high-frequency signal generation unit 2, and a coupler 3. A phase characteristic of the high-frequency signal generation unit 2 is corrected based on the phase characteristic of the high-frequency signal generation unit 2 measured by the phase characteristic measurement apparatus 1.

Specifically, the high-frequency signal generation unit 2 includes a signal source 21, a frequency conversion unit 22, and a local signal generation unit 23, and uses the local signal generation unit 23 that generates a CW local signal and the frequency conversion unit 22 such as a mixer to frequency-convert (up-convert) a signal generated by the signal source 21 into a signal of a high-frequency band and output a high-frequency signal. The coupler 3 branches the high-frequency signal output from the high-frequency signal generation unit 2, outputs one signal as an output signal, and outputs the other signal to the phase characteristic measurement apparatus 1. The phase characteristic measurement apparatus 1 receives the high-frequency signal branched by the coupler 3 and measures a phase characteristic of the input signal.

Specifically, as shown in FIG. 8, the high-frequency signal generation unit 2 includes intermediate frequency signal generators 24a to 24c, an adder 25, a switch 26, the frequency conversion unit 22, the local signal generation unit 23, a waveform memory 27, and a D/A converter 28.

When the switch 26 is set to a contact A, the high-frequency signal generation unit 2 adds (combines) the intermediate frequency signals of the sinusoidal waves generated by the intermediate frequency signal generators 24a to 24c by the adder 25, and the frequency conversion unit 22 frequency-converts (up-converts) the intermediate frequency signals to output as the 3-tone signal of the high-frequency band. In a case where the 2-tone signal is used, the intermediate frequency signal generator having the highest frequency or the intermediate frequency signal generator having the lowest frequency among the intermediate frequency signal generators 24a to 24c is turned off (amplitude is zero). A part of the 3-tone or 2-tone signal output from the high-frequency signal generation unit 2 is transmitted to the phase characteristic measurement apparatus 1 via the coupler 3, and the phase characteristic of the high-frequency signal generation unit 2 is measured.

A signal to be generated by the high-frequency signal generation unit 2 is generated in advance by digital calculation and stored in the waveform memory 27. When the switch 26 is set to a contact B, data of the waveform memory 27 is input to the D/A converter 28 to be converted into an analog signal, and the analog signal is frequency-converted (up-converted) by the frequency conversion unit 22 and output as a high-frequency signal. In this case, by applying an inverse characteristic of the phase characteristic of the high-frequency signal generation unit 2, which is measured in advance, to the signal stored in the waveform memory 27 of the high-frequency signal generation unit 2, a high-frequency signal with a corrected phase characteristic is output, and modulation quality of the high-frequency signal generation unit 2 can be improved. In FIG. 8, the inverse characteristic of the phase characteristic is applied to the signal stored in the waveform memory 27. However, it is also possible to correct the phase characteristic by adding a digital filter (not shown) having the inverse characteristic of the phase characteristic between the waveform memory 27 and the D/A converter 28, and applying the inverse characteristic of the phase characteristic to a digital signal output from the waveform memory 27.

Since the signal generator 100 can output a signal with a corrected phase characteristic, the signal can be used as a reference signal for correcting the phase characteristic of an external high-frequency signal receiving device or the like. In this case, the switch 26 may be set to the contact A to output a 3-tone or 2-tone signal, or may be set to the contact B to output a wideband signal (for example, a multi-tone signal of three or more waves). In a case where the switch 26 is set to the contact A, the inverse characteristic of the phase characteristic of the high-frequency signal generation unit 2 measured by the phase characteristic measurement apparatus 1 may be set to the initial phase of the intermediate frequency signal generators 24a to 24c. In a case where the switch 26 is set to the contact B, a wideband signal with the corrected phase characteristic may be output by applying the inverse characteristic of the phase characteristic of the high-frequency signal generation unit 2 measured by the phase characteristic measurement apparatus 1 to the signal stored in the waveform memory 27. The coupler 3 may be, for example, a switch. In a case where the coupler 3 is replaced with a second switch and the second switch is set to transmit a signal to the phase characteristic measurement apparatus 1, a calibration operation is performed, whereas in a case where the second switch is set to an output side, the switch 26 can be set to the contact B and an operation for generating a signal can be performed.

In addition, as shown in FIG. 9, the waveform memory 27 and the D/A converter 28 may be served as a 2-tone or 3-tone signal source. In a case where the phase characteristic of the high-frequency signal generation unit 2 is measured, the 2-tone or 3-tone signal is stored in the waveform memory 27, and the phase characteristic is measured by the phase characteristic measurement apparatus 1. In a case where the signal generation is performed, a high-frequency signal with the corrected phase characteristic is output by applying the inverse characteristic of the phase characteristic to the signal stored in the waveform memory 27. Alternatively, a digital filter (not shown) having the inverse characteristic of the phase characteristic may be added between the waveform memory 27 and the D/A converter 28 to apply the inverse characteristic of the phase characteristic to the digital signal output from the waveform memory 27.

### Third Embodiment

Next, a signal analyzer provided with the phase characteristic measurement apparatus will be described.

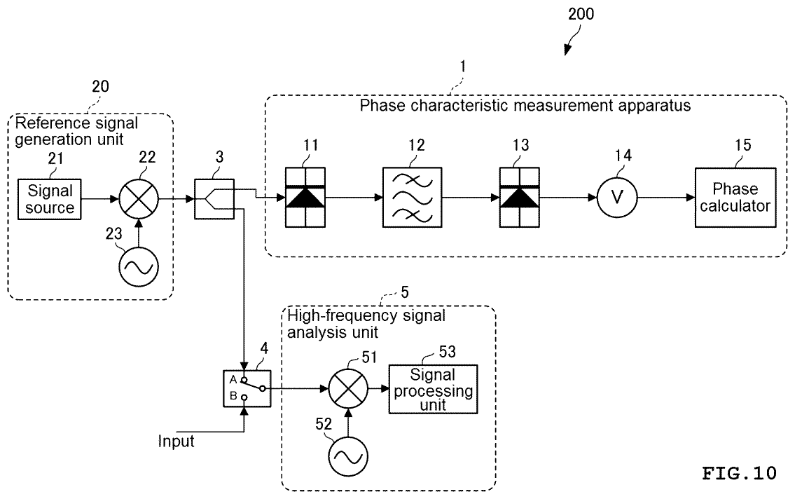

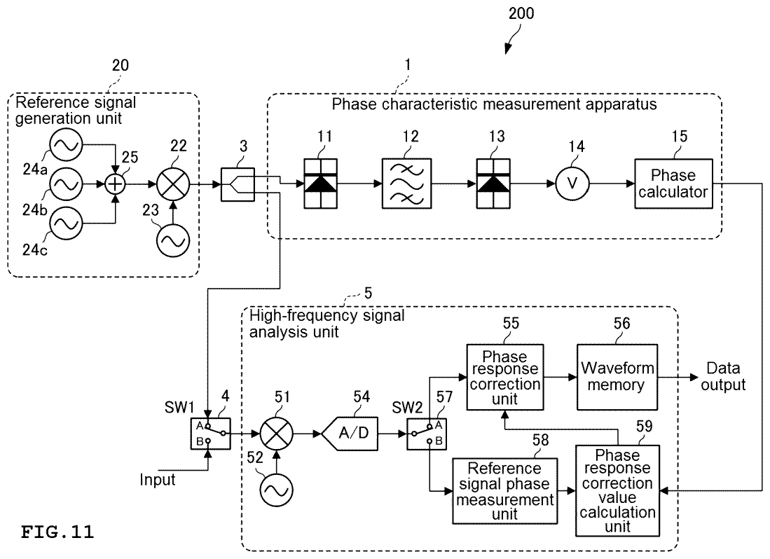

FIG. 10 shows a schematic configuration of a signal analyzer 200 provided with the phase characteristic measurement apparatus 1, and FIG. 11 shows a detailed configuration of the signal analyzer 200. As shown in FIGS. 10 and 11, the signal analyzer 200 includes the phase characteristic measurement apparatus 1, a reference signal generation unit 20, a coupler 3, a switch 4, and a high-frequency signal analysis unit 5. The phase characteristic of the reference signal generation unit 20 is measured by the phase characteristic measurement apparatus 1, and the reference signal having a known phase characteristic is input to the high-frequency signal analysis unit 5 from the reference signal generation unit 20, so that the phase characteristic of the high-frequency signal analysis unit 5 is measured, and the phase characteristic of the high-frequency signal analysis unit 5 is corrected based on the measured phase characteristic of the high-frequency signal analysis unit 5. Then, the high-frequency signal analysis unit 5 with the corrected phase characteristic performs signal analysis of the input signal.

Specifically, the reference signal generation unit 20 includes a signal source 21, a frequency conversion unit 22, and a local signal generation unit 23, and uses the local signal generation unit 23 that generates a CW local signal and the frequency conversion unit 22 such as a mixer to frequency-convert (up-convert) the signal generated by the signal source 21 into a signal of a high-frequency band and output a reference signal. The coupler 3 branches the reference signal output from the reference signal generation unit 20 and outputs one signal to the phase characteristic measurement apparatus 1, and the switch 4 transmits the other signal branched by the coupler 3 to the high-frequency signal analysis unit 5. The phase characteristic measurement apparatus 1 receives the reference signal branched by the coupler 3 and measures the phase characteristic of the input signal. The switch 4 selects one signal of the other signal of the reference signal branched by the coupler 3 or the input signal. The high-frequency signal analysis unit 5 includes a frequency conversion unit 51, a local signal generation unit 52, and a signal processing unit 53, and performs signal analysis by the signal processing unit 53 by frequency-converting (down-converting) the signal selected by the switch 4 by the frequency conversion unit 51 and the local signal generation unit 52.

Specifically, as shown in FIG. 11, the reference signal generation unit 20 includes intermediate frequency signal generators 24a to 24c, an adder 25, a frequency conversion unit 22, and a local signal generation unit 23. The high-frequency signal analysis unit 5 includes a frequency conversion unit 51, a local signal generation unit 52, an A/D converter 54, a phase response correction unit 55, a waveform memory 56, a second switch 57, a reference signal phase measurement unit 58, and a phase response correction value calculation unit 59.

First, the phase characteristic of the reference signal generation unit 20 is measured by the phase characteristic measurement apparatus 1. Specifically, the reference signal generation unit 20 adds (combines) the intermediate frequency signals of the sinusoidal waves generated by the intermediate frequency signal generators 24a to 24c by the adder 25, and the frequency conversion unit 22 frequency-converts (up-converts) the intermediate frequency signals to output as the 3-tone signal of the high-frequency band. In a case where the 2-tone signal is used, the intermediate frequency signal generator having the highest frequency or the intermediate frequency signal generator having the lowest frequency among the intermediate frequency signal generators 24a to 24c is turned off (amplitude is zero). A part of the 3-tone or 2-tone signal output from the reference signal generation unit 20 is transmitted to the phase characteristic measurement apparatus 1 via the coupler 3, and the phase characteristic of the reference signal generation unit 20 is measured.

Next, the switch 4 is set to the contact A, and the second switch 57 is set to the contact B. The phase characteristic of the high-frequency signal analysis unit 5 is measured by inputting a wideband signal (in FIG. 11, a 3-tone signal is shown as the wideband signal, but may be, for example, a multi-tone signal of four or more waves) having a known phase characteristic from the reference signal generation unit 20 to the high-frequency signal analysis unit 5 as the reference signal. Specifically, the reference signal transmitted from the reference signal generation unit 20 via the switch 4 is frequency-converted (down-converted) by the frequency conversion unit 51 and the local signal generation unit 52 in the high-frequency signal analysis unit 5, is converted into a digital signal by the A/D converter 54, and is transmitted to the reference signal phase measurement unit 58 via the second switch 57, and the phase characteristic of the reference signal is measured by the reference signal phase measurement unit 58. In FIG. 11, the reference signal is a 3-tone signal, and the phase characteristic of the reference signal can be obtained by calculating the second-order differential value of the phase of the 3-tone signal which has been frequency-converted and converted into a digital signal, by sweeping the frequency of the 3-tone signal, and by integrating the second-order differential value of the phase twice. In a case where the reference signal is the 3-tone signal, the 3-tone signal is input to both of the phase characteristic measurement apparatus 1 and the high-frequency signal analysis unit 5. Therefore, it is also possible to simultaneously perform the measurement of the phase characteristic of the reference signal generation unit 20 by the phase characteristic measurement apparatus 1 and the measurement of the phase characteristic of the reference signal by the high-frequency signal analysis unit 5. In a case where the reference signal is a multi-tone signal of four or more waves, the second-order differential values of the phase at a plurality of frequencies can be obtained at once, so that the phase characteristic of the reference signal can be obtained with a small number of frequency sweep points. The phase response correction value calculation unit 59 calculates the phase characteristic of the high-frequency signal analysis unit 5 from the phase characteristic of the reference signal measured by the reference signal phase measurement unit 58 and the phase characteristic of the reference signal generation unit 20 measured by the phase characteristic measurement apparatus 1. That is, the phase characteristic of the high-frequency signal analysis unit 5 is obtained by subtracting the phase characteristic of the reference signal generation unit 20 measured by the phase characteristic measurement apparatus 1 from the phase characteristic of the reference signal measured by the reference signal phase measurement unit 58. Here, the phase characteristic of the high-frequency signal analysis unit 5 is calculated from the phase characteristic of the reference signal measured by the reference signal phase measurement unit 58 and the phase characteristic of the reference signal generation unit 20 measured by the phase characteristic measurement apparatus 1, but the phase of the reference signal generated by the reference signal generation unit 20 may be corrected by setting the inverse characteristic of the phase characteristic of the reference signal generation unit 20 measured by the phase characteristic measurement apparatus 1 to the initial phase of the intermediate frequency signal generators 24a to 24c. In this case, since the reference signal with the corrected phase characteristic is input to the high-frequency signal analysis unit 5, the phase characteristic of the reference signal measured by the reference signal phase measurement unit 58 becomes the phase characteristic of the high-frequency signal analysis unit 5.

When the switch 4 is set to the contact B and the second switch 57 is set to the contact A, the input signal is frequency-converted (down-converted) by the frequency conversion unit 51 and the local signal generation unit 52 and converted into a digital signal by the A/D converter 54, and the phase characteristic of the high-frequency signal analysis unit 5 is corrected by the phase response correction unit 55, is stored in the waveform memory 56, and output as analysis data. That is, in the phase response correction unit 55, signal analysis in which the phase characteristic of the high-frequency signal analysis unit 5 is corrected is performed by applying a digital filter having the inverse characteristic of the phase characteristic of the high-frequency signal analysis unit 5 calculated by the phase response correction value calculation unit 59 to the digital signal output from the A/D converter 54, and analysis quality (demodulation quality) can be improved.

In FIG. 11, the phase characteristic is corrected by applying a digital filter having the inverse characteristic of the phase characteristic of the high-frequency signal analysis unit 5 to the digital signal output from the A/D converter 54, but the phase characteristic may be corrected by once storing the digital signal output from the A/D converter 54 in the waveform memory 56 and applying the inverse characteristic of the phase characteristic to waveform data in the waveform memory 56 by an offline process. In addition, the coupler 3 in the drawings may be, for example, a switch, and the switch 4 may be, for example, a coupler.

### INDUSTRIAL APPLICABILITY

As described above, the present invention has an effect of realizing a phase measurement at a relatively low cost without increasing the scale of an apparatus used for the phase measurement by using a voltmeter and a detector that do not require a high-speed trigger operation, and is useful in general for a phase characteristic measurement apparatus, a signal generator and a signal analyzer having the same, and a phase characteristic measurement method.

### DESCRIPTION OF REFERENCE NUMERALS AND SIGNS

1: Phase Characteristic Measurement Apparatus
10: Phase Characteristic Measurement System
11: First Detector
12: Band-pass Filter (BPF)
13: Second Detector
14: Voltmeter
15: Phase Calculator
2: High-frequency Signal Generation Unit
20: Reference Signal Generation Unit
21: Signal Source
22: Frequency Conversion Unit
23: Local Signal Generation Unit
24a, 24b, 24c: Intermediate Frequency Signal Generator
25: Adder
26: Switch
27: Waveform Memory
28: D/A Converter
3: Coupler
4: Switch
5: High-frequency Signal Analysis Unit
51: Frequency Conversion Unit
52: Local Signal Generation Unit
53: Signal Processing Unit
54: A/D Converter
55: Phase Response Correction Unit
56: Waveform Memory
57: Second Switch
58: Reference Signal Phase Measurement Unit
59: Phase Response Correction Value Calculation Unit
100: Signal Generator
200: Signal Analyzer

What is claimed is:

1. A phase characteristic measurement apparatus comprising:
a first detector that receives and detects a first 3-tone signal obtained by combining three waves e₁, e₂, and e₃ represented by Equation (1) and a second 3-tone signal obtained by combining three waves e₁, e₂, and e₃ represented by Equation (2) as a signal for phase measurements, respectively;
a band-pass filter that, among signals output from the first detector, allows a frequency component of an angular frequency difference CO between waves with adjacent frequencies of each of the signals for phase measurements to pass and blocks a frequency component twice the angular frequency difference Δω and a direct current component;
a second detector that detects a signal that has passed through the band-pass filter;
a voltmeter that measures a voltage of a signal output from the second detector; and
a phase calculator that calculates a phase φ₂″ represented by Equation (3)
$$[ Equation 1 ]$$
$${e}_{i} = cos ( {ω}_{i} t + {ϕ}_{i} ) , i = 1 , 2 , 3 \qquad ( 1 )$$
$$[ Equation 2 ]$$
$${e}_{i} = cos ( {ω}_{i} t + {ϕ}_{i} + {α}_{i} ) , i = 1 , 2 , 3 \qquad ( 2 )$$
$$[ Equation 3 ]$$
$${ϕ}_{2}^{′′} = \{ \begin{matrix}\frac{2}{{Δω}^{2}} {tan}^{- 1} ( \frac{\sqrt{\frac{{E}_{beat} ( {ϕ}_{α} )}{{E}_{beat} ( 0 )}} + cos ( \frac{{ϕ}_{α}}{2} )}{sin ( \frac{{ϕ}_{α}}{2} )} ) , & π - {ϕ}_{α} \leq {ϕ}_{3} - 2 {ϕ}_{2} + {ϕ}_{1} \leq π \\ \frac{2}{{Δω}^{2}} {tan}^{- 1} ( \frac{- \sqrt{\frac{{E}_{beat} ( {ϕ}_{α} )}{{E}_{beat} ( 0 )}} + cos ( \frac{{ϕ}_{α}}{2} )}{sin ( \frac{{ϕ}_{α}}{2} )} ) , & - π \leq {ϕ}_{3} - 2 {ϕ}_{2} + {ϕ}_{1} \leq π - {ϕ}_{α}\end{matrix} \qquad ( 3 )$$
(in Equations (1), (2), and (3),
ωᵢ represent angular frequencies, φᵢ represent phases, t represents a time, and ω₂−ω₁=ω₃−ω₂=Δω is established,
αᵢ are phase offsets of the second 3-tone signal, and φ_{α}=α₃−2α₂+α₁ is established when a second-order difference of αᵢ is represented by φ_{α},
E_{beat}(φ_{α}) represents a value that is obtained from a voltage value measured by the voltmeter and that is proportional to power of the signal that has passed through the band-pass filter, in a case where the second 3-tone signal in which the second-order difference of αᵢ is set to φ_{α} is detected by the first detector, and
E_{beat}(0) represents a value that is obtained from a voltage value measured by the voltmeter and that is proportional to power of the signal that has passed through the band-pass filter, in a case where the first 3-tone signal is detected by the first detector).

2. A phase characteristic measurement apparatus comprising:
a first detector that receives and detects a first 3-tone signal obtained by combining three waves e₁, e₂, and e₃ represented by Equation (4), a second 3-tone signal obtained by combining three waves e₁, e₂, and e₃ represented by Equation (5), and a third 3-tone signal obtained by combining three waves e₁, e₂, and e₃ represented by Equation (6) as a signal for phase measurements, respectively;
a second detector that detects a signal output from the first detector;
a voltmeter that measures a voltage of a signal output from the second detector; and
a phase calculator that calculates a phase φ₂″ represented by Equation (7) or Equation (11),
$$[ Equation 4 ]$$
$${e}_{i} = {a}_{i} cos ( {ω}_{i} t + {ϕ}_{i} ) , i = 1 , 2 , 3 \qquad ( 4 )$$
$$[ Equation 5 ]$$
$${e}_{i} = {a}_{i} cos ( {ω}_{i} t + {ϕ}_{i} + {α}_{3 i} ) , i = 1 , 2 , 3 \qquad ( 5 )$$
$$[ Equation 6 ]$$
$${e}_{i} = {a}_{i} cos ( {ω}_{i} t + {ϕ}_{i} + {α}_{2 i} ) , i = 1 , 2 , 3 \qquad ( 6 )$$
$$[ Equation 7 ]$$
$${ϕ}_{2}^{′′} = \frac{1}{{Δω}^{2}} ( {tan}^{- 1} ( \frac{cos ( {Δϕ}_{α 2} )}{cos ( {Δϕ}_{α 1} ) + sin ( {Δϕ}_{α 2} )} ( \frac{{E}_{beat} ( 0 ) - 2 {E}_{beat} ( {ϕ}_{α 1} ) + {E}_{beat} ( {ϕ}_{α 2} )}{{E}_{beat} ( 0 ) - {E}_{beat} ( {ϕ}_{α 2} )} - \frac{sin ( {Δϕ}_{α 1} )}{cos ( {Δϕ}_{α 2} )} ) ) - {Δϕ}_{α 2} ) \qquad ( 7 )$$
$$[ Equation 11 ]$$
$${ϕ}_{2}^{′′} = \frac{1}{{Δω}^{2}} ( atan 2 ( \frac{cos ( {Δϕ}_{α 2} )}{cos ( {Δϕ}_{α 1} ) + sin ( Δ {ϕ}_{α 2} )} ( cos ( {Δϕ}_{α 2} ) ( {E}_{beat} ( 0 ) - 2 {E}_{beat} ( {ϕ}_{α 1} ) + {E}_{beat} ( {ϕ}_{α 2} ) ) - sin ( Δ {ϕ}_{α 1} ) ( {E}_{beat} ( 0 ) - {E}_{beat} ( {ϕ}_{α 2} ) ) ) , cos ( {Δϕ}_{α 2} ) ( {E}_{beat} ( 0 ) - {E}_{beat} ( {ϕ}_{α 2} ) ) ) - {Δϕ}_{α 2} ) \qquad ( 11 )$$
(in Equations (4), (5), (6), (7), and (11),
aᵢ represent amplitudes, ωᵢ represent angular frequencies, φᵢ represent phases, t represents a time, and ω₂−ω₁=ω₃−ω₂=Δω is established,
α₁ᵢ are phase offsets of the second 3-tone signal, and φ_{α1}=α₁₃−2αᵢ+α₁₁ is established when a second-order difference of α₁ᵢ is represented by φ_{α1},
α₂ᵢ are phase offsets of the third 3-tone signal, and φ_{α2}=α₂₃−2α₂₂+α₂₁ is established when a second-order difference of α₂ᵢ is represented by φ_{α2},
φ_{α1}=π/2+Δφ_{α1}+Δφ_{α2}, and φ_{α2}=π+2Δφ_{α2} are established,
E_{beat}(0) represents a value that is obtained from a voltage value measured by the voltmeter and that is proportional to power of the signal output from the first detector, in a case where the first 3-tone signal is detected by the first detector,
E_{beat}(φ_{α1}) represents a value that is obtained from a voltage value measured by the voltmeter and that is proportional to power of the signal output from the first detector, in a case where the second 3-tone signal in which the second-order difference of α₁ᵢ is set to φ_{α1} is detected by the first detector, and
E_{beat}(φ_{α2}) represents a value that is obtained from a voltage value measured by the voltmeter and that is proportional to power of the signal output from the first detector, in a case where the third 3-tone signal in which the second-order difference of α₂ᵢ is set to φ_{α2} is detected by the first detector).

3. A phase characteristic measurement apparatus comprising:
a first detector that receives and detects a first 3-tone signal obtained by combining three waves e₁, e₂, and e₃ represented by Equation (12), a second 3-tone signal obtained by combining three waves e₁, e₂, and e₃ represented by Equation (13), a third 3-tone signal obtained by combining three waves e₁, e₂, and e₃ represented by Equation (14), and a fourth 3-tone signal obtained by combining three waves e₁, e₂, and e₃ represented by Equation (15) as a signal for phase measurements, respectively;
a second detector that detects a signal output from the first detector;
a voltmeter that measures a voltage of a signal output from the second detector; and
a phase calculator that calculates a phase φ₂″ represented by Equation (16) or Equation (21),
$$[ Equation 12 ]$$
$${e}_{i} = {a}_{i} cos ( {ω}_{i} t + {ϕ}_{i} ) , i = 1 , 2 , 3 \qquad ( 12 )$$
$$[ Equation 13 ]$$
$${e}_{i} = {a}_{i} cos ( {ω}_{i} t + {ϕ}_{i} + {α}_{1 i} ) , i = 1 , 2 , 3 \qquad ( 13 )$$
$$[ Equation 14 ]$$
$${e}_{i} = {a}_{i} cos ( {ω}_{i} t + {ϕ}_{i} + {α}_{2 i} ) , i = 1 , 2 , 3 \qquad ( 14 )$$
$$[ Equation 15 ]$$
$${e}_{i} = {a}_{i} cos ( {ω}_{i} t + {ϕ}_{i} + {α}_{3 i} ) , i = 1 , 2 , 3 \qquad ( 15 )$$
$$[ Equation 16 ]$$
$${ϕ}_{2}^{′′} = \frac{1}{{Δω}^{2}} ( {tan}^{- 1} ( \frac{2 cos ( {Δϕ}_{α 2} )}{cos ( Δ {ϕ}_{α 1} ) + cos ( {Δϕ}_{α 3} )} ( \frac{{E}_{beat} ( {ϕ}_{α 3} ) - {E}_{beat} ( {ϕ}_{α 1} )}{{E}_{beat} ( 0 ) - {E}_{beat} ( {ϕ}_{α 2} )} - \frac{sin ( {Δϕ}_{α 1} ) + sin ( {Δϕ}_{α 3} )}{2 cos ( {Δϕ}_{α 2} )} ) ) - {Δϕ}_{α 2} ) \qquad ( 16 )$$
$$[ Equation 21 ]$$
$${ϕ}_{2}^{′′} = \frac{1}{{Δω}^{2}} ( atan 2 ( \frac{2 cos ( {Δϕ}_{α 2} )}{cos ( Δ {ϕ}_{α 1} ) + cos ( Δ {ϕ}_{α 3} )} ( 2 cos ( Δ {ϕ}_{α 2} ) ( {E}_{beat} ( {ϕ}_{α 3} ) - {E}_{beat} ( {ϕ}_{α 1} ) ) - ( sin ( {Δϕ}_{α 1} ) + sin ( Δ {ϕ}_{α 3} ) ) ( {E}_{beat} ( 0 ) - {E}_{beat} ( {ϕ}_{α 2} ) ) ) , 2 cos ( {Δϕ}_{α 2} ) ( {E}_{beat} ( 0 ) - {E}_{beat} ( {ϕ}_{α 2} ) ) ) - {Δϕ}_{α 2} ) \qquad ( 21 )$$
(in Equations (12), (13), (14), (15), (16), and (21),
αᵢ represent amplitudes, ωᵢ represent angular frequencies, φᵢ represent phases, t represents a time, and ω₂−ω₁=ω₃−ω₂=Δω is established,
α₁ᵢ are phase offsets of the second 3-tone signal, and φ_{α1}=α₁₃−2α₁₂+α₁₁ is established when a second-order difference of α₁₁ is represented by φ_{α1},
α₂ᵢ are phase offsets of the third 3-tone signal, and φ_{α2}=α₂₃−2α₂₂+α₂₁ is established when a second-order difference of α₂ᵢ is represented by φ_{α2},
α₃ᵢ are phase offsets of the fourth 3-tone signal, and φ_{α3}=α₃₃−2α₃₂+α₃₁ is established when a second-order difference of α₃ᵢ is represented by φ_{α3},
φ_{α1}=π/2+Δφ_{α1}+Δφ_{α2}, φ_{α2}=π+2Δφ_{α2}, and φ_{α3}=3π/2+Δφ_{α3}+Δφ_{α2} are established,
E_{beat}(0) represents a value that is obtained from a voltage value measured by the voltmeter and that is proportional to power of the signal output from the first detector, in a case where the first 3-tone signal is detected by the first detector,
E_{beat}(φ_{α1}) represents a value that is obtained from a voltage value measured by the voltmeter and that is proportional to power of the signal output from the first detector, in a case where the second 3-tone signal in which the second-order difference of α₁ᵢ is set to φ_{α1} is detected by the first detector, E_{beat}(φ_{α2}) represents a value that is obtained from a voltage value measured by the voltmeter and that is proportional to power of the signal output from the first detector, in a case where the third 3-tone signal in which the second-order difference of α₂ᵢ is set to φ_{α2} is detected by the first detector, and
E_{beat}(φ_{α3}) represents a value that is obtained from a voltage value measured by the voltmeter and that is proportional to power of the signal output from the first detector, in a case where the fourth 3-tone signal in which the second-order difference of α₃ᵢ is set to φ_{α3} is detected by the first detector).

4. A phase characteristic measurement apparatus comprising:
a first detector that receives and detects a first 2-tone signal obtained by combining two waves e₁ and e₂ represented by Equation (22), a second 2-tone signal obtained by combining two waves e₂ and e₃ represented by Equation (23), a first 3-tone signal obtained by combining three waves e₁, e₂, and e₃ represented by Equation (24), and a second 3-tone signal obtained by combining three waves e₁, e₂, and e₃ represented by Equation (25) as a signal for phase measurements, respectively;
a band-pass filter that, among signals output from the first detector, allows a frequency component of an angular frequency difference Δω between waves with adjacent frequencies of each of the signals for phase measurements to pass and blocks a frequency component twice the angular frequency difference Δω and a direct current component;
a second detector that detects a signal that has passed through the band-pass filter;
a voltmeter that measures a voltage of a signal output from the second detector; and
a phase calculator that calculates a phase φ₂″ represented by Equation (26) or Equation (31),
$$[ Equation 22 ]$$
$${e}_{i} = {a}_{i} cos ( {ω}_{i} t + {ϕ}_{i} + {γ}_{i} ) , i = 1 , 2 \qquad ( 22 )$$
$$[ Equation 23 ]$$
$${e}_{i} = {a}_{i} cos ( {ω}_{i} t + {ϕ}_{i} + {γ}_{i} ) , i = 2 , 3 \qquad ( 23 )$$
$$[ Equation 24 ]$$
$${e}_{i} = {a}_{i} cos ( {ω}_{i} t + {ϕ}_{i} ) , i = 1 , 2 , 3 \qquad ( 24 )$$
$$[ Equation 25 ]$$
$${e}_{i} = {a}_{i} cos ( {ω}_{i} t + {ϕ}_{i} + {α}_{1 i} ) , i = 1 , 2 , 3 \qquad ( 25 )$$
$$[ Equation 26 ]$$
$${ϕ}_{2}^{′′} = \frac{1}{{Δω}^{2}} {tan}^{- 1} ( \frac{1}{cos ( {Δϕ}_{α 1} )} ( - \frac{{E}_{beat} ( {ϕ}_{α 1} ) - {E}_{beat} ( {a}_{3} = 0 ) - {E}_{beat} ( {a}_{1} = 0 )}{{E}_{beat} ( 0 ) - {E}_{beat} ( {a}_{3} = 0 ) - {E}_{beat} ( {a}_{1} = 0 )} - sin ( Δ {ϕ}_{α 1} ) ) ) \qquad ( 26 )$$
$$[ Equation 31 ]$$
$${ϕ}_{2}^{′′} = \frac{1}{{Δω}^{2}} atan 2 ( \frac{1}{cos ( {Δϕ}_{α 1} )} ( - {E}_{beat} ( {ϕ}_{α 1} ) - {E}_{beat} ( {a}_{3} = 0 ) + {E}_{beat} ( {a}_{1} = 0 ) - sin ( {Δϕ}_{α 1} ) ( {E}_{beat} ( 0 ) - {E}_{beat} ( {a}_{3} = 0 ) - {E}_{beat} ( {a}_{1} = 0 ) ) ) , {E}_{beat} ( 0 ) - {E}_{beat} ( {a}_{3} = 0 ) - {E}_{beat} ( {a}_{1} = 0 ) ) \qquad ( 31 )$$
(in Equations (22), (23), (24), (25), (26), and (31),
αᵢ represent amplitudes, ωᵢ represent angular frequencies, φᵢ represent phases, γᵢ represent arbitrary phases, t represents a time, and ω₂−ω₁=ω₃−ω₂=Δω is established,
α₁ᵢ are phase offsets of the second 3-tone signal, and φ_{α1}=α₁₃−2α₁₂+α₁₁ is established when a second-order difference of α₁ᵢ is represented by φ_{α1},
φ_{α1}=π/2+Δφ_{α1} is established,
E_{beat}(φ_{α1}) represents a value that is obtained from a voltage value measured by the voltmeter and that is proportional to power of the signal that has passed through the band-pass filter, in a case where the second 3-tone signal in which the second-order difference of an is set to φ_{α1} is detected by the first detector,
E_{beat}(0) represents a value that is obtained from a voltage value measured by the voltmeter and that is proportional to power of the signal that has passed through the band-pass filter, in a case where the first 3-tone signal is detected by the first detector,
E_{beat}(a₁=0) represents a value that is obtained from a voltage value measured by the voltmeter and that is proportional to power of the signal that has passed through the band-pass filter, in a case where the second 2-tone signal is detected by the first detector, and
E_{beat}(a₃=0) represents a value that is obtained from a voltage value measured by the voltmeter and that is proportional to power of the signal that has passed through the band-pass filter, in a case where the first 2-tone signal is detected by the first detector).

5. A phase characteristic measurement apparatus comprising:
a first detector that receives and detects a first 2-tone signal obtained by combining two waves e₁ and e₂ represented by Equation (32), a second 2-tone signal obtained by combining two waves e₂ and e₃ represented by Equation (33), and a 3-tone signal obtained by combining three waves e₁, e₂, and e₃ represented by Equation (34) as a signal for phase measurements, respectively;
a band-pass filter that, among signals output from the first detector, allows a frequency component of an angular frequency difference CO between waves with adjacent frequencies of each of the signals for phase measurements to pass and blocks a frequency component twice the angular frequency difference Δω and a direct current component;
a second detector that detects a signal that has passed through the band-pass filter;
a voltmeter that measures a voltage of a signal output from the second detector; and
a phase calculator that calculates a phase φ₂″ represented by Equation (35),
$$[ Equation 32 ]$$
$${e}_{i} = {a}_{i} cos ( {ω}_{i} t + {ϕ}_{i} + {γ}_{i} ) , i = 1 , 2 \qquad ( 32 )$$
$$[ Equation 33 ]$$
$${e}_{i} = {a}_{i} cos ( {ω}_{i} t + {ϕ}_{i} + {γ}_{i} ) , i = 2 , 3 \qquad ( 33 )$$
$$[ Equation 34 ]$$
$${e}_{i} = {a}_{i} cos ( {ω}_{i} t + {ϕ}_{i} ) , i = 1 , 2 , 3 \qquad ( 34 )$$
$$[ Equation 35 ]$$
$${ϕ}_{2}^{′′} = \frac{1}{{Δω}^{2}} {cos}^{- 1} ( \frac{{E}_{beat} ( 0 ) - {E}_{beat} ( {a}_{3} = 0 ) - {E}_{beat} ( {a}_{1} = 0 )}{2 \sqrt{{E}_{beat} ( {a}_{1} = 0 ) {E}_{beat} ( {a}_{3} = 0 )}} ) \qquad ( 35 )$$
(in Equations (32), (33), (34), and (35),
aᵢ represent amplitudes, ωᵢ represent angular frequencies, φᵢ represent phases, γᵢ represent arbitrary phases, t represents a time, and ω₂−ω₁=ω₃−ω₂=Δω is established,
E_{beat}(0) represents a value that is obtained from a voltage value measured by the voltmeter and that is proportional to power of the signal that has passed through the band-pass filter, in a case where the 3-tone signal is detected by the first detector,
E_{beat}(a₁=0) represents a value that is obtained from a voltage value measured by the voltmeter and that is proportional to power of the signal that has passed through the band-pass filter, in a case where the second 2-tone signal is detected by the first detector, and
E_{beat}(a₃=0) represents a value that is obtained from a voltage value measured by the voltmeter and that is proportional to power of the signal that has passed through the band-pass filter, in a case where the first 2-tone signal is detected by the first detector).

6. A signal generator comprising:
a high-frequency signal generation unit that generates a high-frequency signal and the signal for phase measurements;
a coupler that branches a signal output from the high-frequency signal generation unit and outputs one signal as an output signal; and
the phase characteristic measurement apparatus according to claim 1 in which, when the high-frequency signal generation unit generates the signal for phase measurements, the other signal branched by the coupler is input, and the phase φ₂″ is measured from the input signal for phase measurements to measure a phase characteristic of the high-frequency signal generation unit,
wherein when the high-frequency signal generation unit generates the high-frequency signal, a phase characteristic of the high-frequency signal is corrected based on the phase characteristic of the high-frequency signal generation unit measured by the phase characteristic measurement apparatus.

7. A signal analyzer comprising:
a reference signal generation unit that generates a reference signal and the signal for phase measurements;
a coupler that branches a signal output from the reference signal generation unit;
the phase characteristic measurement apparatus according to claim 1 in which, when the reference signal generation unit generates the signal for phase measurements, one signal branched by the coupler is input, and the phase φ₂″ is measured from the input signal for phase measurements to measure a phase characteristic of the reference signal generation unit;
a switch that selects one signal of the other signal branched by the coupler or an input signal; and
a high-frequency signal analysis unit that analyzes the signal selected by the switch,
wherein a phase characteristic of the high-frequency signal analysis unit is calculated from a phase characteristic of the reference signal measured by the high-frequency signal analysis unit when the reference signal generation unit generates the reference signal and the other signal branched by the coupler is selected by the switch, and the phase characteristic of the reference signal generation unit measured by the phase characteristic measurement apparatus, a phase characteristic in a case where the high-frequency signal analysis unit analyzes the input signal is corrected based on the calculated phase characteristic of the high-frequency signal analysis unit, when the input signal is selected by the switch, and signal analysis of the input signal is performed with the corrected phase characteristic.

8. A phase characteristic measurement method comprising:
a signal for phase measurements generation step of generating, as a signal for phase measurements, a first 3-tone signal obtained by combining three waves e₁, e₂, and e₃ represented by Equation (36) and a second 3-tone signal obtained by combining three waves e₁, e₂, and e₃ represented by Equation (37);
a first detection step of detecting the signal for phase measurements;
a band-pass filter step of, among signals obtained in the first detection step, allowing a frequency component of an angular frequency difference Δω between waves with adjacent frequencies of each of the signals for phase measurements to pass and blocking a frequency component twice the angular frequency difference Δω and a direct current component;
a second detection step of detecting a signal that has passed in the band-pass filter step;
a voltage measurement step of measuring a voltage of a signal obtained in the second detection step; and
a phase calculation step of calculating a phase φ₂″ represented by Equation (38),
$$[ Equation 36 ]$$
$${e}_{i} = cos ( {ω}_{i} t + {ϕ}_{i} ) , i = 1 , 2 , 3 \qquad ( 36 )$$
$$[ Equation 37 ]$$
$${e}_{i} = cos ( {ω}_{i} t + {ϕ}_{i} + {α}_{i} ) , i = 1 , 2 , 3 \qquad ( 37 )$$
$$[ Equation 38 ]$$
$${ϕ}_{2}^{′′} = \{ \begin{matrix}\frac{2}{{Δω}^{2}} {tan}^{- 1} ( \frac{\sqrt{\frac{{E}_{beat} ( {ϕ}_{α} )}{{E}_{beat} ( 0 )}} + cos ( \frac{{ϕ}_{α}}{2} )}{sin ( \frac{{ϕ}_{α}}{2} )} ) , & π - {ϕ}_{α} \leq {ϕ}_{3} - 2 {ϕ}_{2} + {ϕ}_{1} \leq π \\ \frac{2}{{Δω}^{2}} {tan}^{- 1} ( \frac{- \sqrt{\frac{{E}_{beat} ( {ϕ}_{α} )}{{E}_{beat} ( 0 )}} + cos ( \frac{{ϕ}_{α}}{2} )}{sin ( \frac{{ϕ}_{α}}{2} )} ) , & - π \leq {ϕ}_{3} - 2 {ϕ}_{2} + {ϕ}_{1} \leq π - {ϕ}_{α}\end{matrix} \qquad ( 38 )$$
(in Equations (36), (37), and (38),
ωᵢ represent angular frequencies, φᵢ represent phases, t represents a time, and ω₂−ω₁=ω₃−ω₂=Δω is established,
αᵢ are phase offsets of the second 3-tone signal, and φ_{α}=α₃−2α₂+α₁ is established when a second-order difference of αᵢ is represented by φ_{α},
E_{beat}(φ_{α}) represents a value that is obtained from a voltage value measured in the voltage measurement step and that is proportional to power of the signal that has passed in the band-pass filter step in a case where the second 3-tone signal in which the second-order difference of αᵢ is set to φ_{α} is detected in the first detection step, and
E_{beat}(0) represents a value that is obtained from a voltage value measured in the voltage measurement step and that is proportional to power of the signal that has passed in the band-pass filter step in a case where the first 3-tone signal is detected in the first detection step).

9. A phase characteristic measurement method comprising:
a signal for phase measurements generation step of generating, as a signal for phase measurements, a first 3-tone signal obtained by combining three waves e₁, e₂, and e₃ represented by Equation (39), a second 3-tone signal obtained by combining three waves e₁, e₂, and e₃ represented by Equation (40), and a third 3-tone signal obtained by combining three waves e₁, e₂, and e₃ represented by Equation (41);
a first detection step of detecting the signal for phase measurements;
a second detection step of detecting a signal obtained in the first detection step;
a voltage measurement step of measuring a voltage of a signal obtained in the second detection step; and
a phase calculation step of calculating a phase φ₂″ represented by Equation (42) or Equation (46),
$$[ Equation 39 ]$$
$${e}_{i} = {a}_{i} cos ( {ω}_{i} t + {ϕ}_{i} ) , i = 1 , 2 , 3 \qquad ( 39 )$$
$$[ Equation 40 ]$$
$${e}_{i} = {a}_{i} cos ( {ω}_{i} t + {ϕ}_{i} + {α}_{1 i} ) , i = 1 , 2 , 3 \qquad ( 40 )$$
$$[ Equation 41 ]$$
$${e}_{i} = {a}_{i} cos ( {ω}_{i} t + {ϕ}_{i} + {α}_{2 i} ) , i = 1 , 2 , 3 \qquad ( 41 )$$
$$[ Equation 42 ]$$
$${ϕ}_{2}^{′′} = \frac{1}{{Δω}^{2}} ( {tan}^{- 1} ( \frac{cos ( {Δϕ}_{α 2} )}{cos ( {Δϕ}_{α 3} ) + sin ( {Δϕ}_{α 2} )} ( \frac{{E}_{beat} ( 0 ) - 2 {E}_{beat} ( {ϕ}_{α 1} ) + {E}_{beat} ( {ϕ}_{α 2} )}{{E}_{beat} ( 0 ) - {E}_{beat} ( {ϕ}_{α 2} )} - \frac{sin ( {Δϕ}_{α 1} )}{cos ( {Δϕ}_{α 2} )} ) ) - {Δϕ}_{α 2} ) \qquad ( 42 )$$
$$[ Equation 46 ]$$
$${ϕ}_{2}^{′′} = \frac{1}{{Δω}^{2}} ( atan 2 ( \frac{cos ( {Δϕ}_{α 2} )}{cos ( Δ {ϕ}_{α 1} ) + sin ( {Δϕ}_{α 2} )} ( cos ( {Δϕ}_{α 2} ) ( {E}_{beat} ( 0 ) - 2 {E}_{beat} ( {ϕ}_{α 1} ) + {E}_{beat} ( {ϕ}_{α 2} ) ) - sin ( {Δϕ}_{α 1} ) ( {E}_{beat} ( 0 ) - {E}_{beat} ( {ϕ}_{α 2} ) ) ) , cos ( {Δϕ}_{α 2} ) ( {E}_{beat} ( 0 ) - {E}_{beat} ( {ϕ}_{α 2} ) ) ) - {Δϕ}_{α 2} ) \qquad ( 46 )$$
(in Equations (39), (40), (41), (42), and (46),
aᵢ represent amplitudes, ωᵢ represent angular frequencies, φᵢ represent phases, t represents a time, and ω₂−ω₁=ω₃−ω₂=Δω is established,
α₁ᵢ are phase offsets of the second 3-tone signal, and φ_{α1}=α₁₃−2α₁₂+α₁₁ is established when a second-order difference of α₁ᵢ is represented by φ_{α1},
α₂ᵢ are phase offsets of the third 3-tone signal, and φ_{α2}=α₂₃−2α₂₂+α₂₁ is established when a second-order difference of α₂₁ is represented by φ_{α2},
φ_{α1}=π/2+Δφ_{α1}+Δφ_{α2}, and φ_{α2}=π+2Δφ_{α2} are established,
E_{beat}(0) represents a value that is obtained from a voltage value measured in the voltage measurement step and that is proportional to power of the signal obtained in the first detection step in a case where the first 3-tone signal is detected in the first detection step,
E_{beat}(φ_{α1}) represents a value that is obtained from a voltage value measured in the voltage measurement step and that is proportional to power of the signal obtained in the first detection step in a case where the second 3-tone signal in which the second-order difference of α₁ᵢ is set to φ_{α1} is detected in the first detection step, and
E_{beat}(φ_{α2}) represents a value that is obtained from a voltage value measured in the voltage measurement step and that is proportional to power of the signal obtained in the first detection step in a case where the third 3-tone signal in which the second-order difference of α₂ᵢ is set to φ_{α2} is detected in the first detection step).

10. A phase characteristic measurement method comprising:
a signal for phase measurements generation step of generating, as a signal for phase measurements, a first 3-tone signal obtained by combining three waves e₁, e₂, and e₃ represented by Equation (47), a second 3-tone signal obtained by combining three waves e₁, e₂, and e₃ represented by Equation (48), a third 3-tone signal obtained by combining three waves e₁, e₂, and e₃ represented by Equation (49), and a fourth 3-tone signal obtained by combining three waves e₁, e₂, and e₃ represented by Equation (50);
a first detection step of detecting the signal for phase measurements;
a second detection step of detecting a signal obtained in the first detection step;
a voltage measurement step of measuring a voltage of a signal obtained in the second detection step; and
a phase calculation step of calculating a phase φ₂″ represented by Equation (51) or Equation (56),
$$[ Equation 47 ]$$
$${e}_{i} = {a}_{i} cos ( {ω}_{i} t + {ϕ}_{i} ) , i = 1 , 2 , 3 \qquad ( 47 )$$
$$[ Equation 48 ]$$
$${e}_{i} = {a}_{i} cos ( {ω}_{i} t + {ϕ}_{i} + {α}_{1 i} ) , i = 1 , 2 , 3 \qquad ( 48 )$$
$$[ Equation 49 ]$$
$${e}_{i} = {a}_{i} cos ( {ω}_{i} t + {ϕ}_{i} + {α}_{2 i} ) , i = 1 , 2 , 3 \qquad ( 49 )$$
$$[ Equation 50 ]$$
$${e}_{i} = {a}_{i} cos ( {ω}_{i} t + {ϕ}_{i} + {α}_{3 i} ) , i = 1 , 2 , 3 \qquad ( 50 )$$
$$[ Equation 51 ]$$
$${ϕ}_{2}^{′′} = \frac{1}{{Δω}^{2}} ( {tan}^{- 1} ( \frac{2 cos ( {Δϕ}_{α 2} )}{cos ( {Δϕ}_{α 3} ) + cos ( {Δϕ}_{α 2} )} ( \frac{{E}_{beat} ( {ϕ}_{α 2} ) - {E}_{beat} ( {ϕ}_{α 1} )}{{E}_{beat} ( 0 ) - {E}_{beat} ( {ϕ}_{α 2} )} - \frac{sin ( {Δϕ}_{α 3} ) + sin ( {Δϕ}_{α 1} )}{2 cos ( {Δϕ}_{α 2} )} ) ) - {Δϕ}_{α 2} ) \qquad ( 51 )$$
$$[ Equation 56 ]$$
$${ϕ}_{2}^{′′} = \frac{1}{{Δω}^{2}} ( atan 2 ( \frac{2 cos ( {Δϕ}_{α 2} )}{cos ( Δ {ϕ}_{α 1} ) + cos ( {Δϕ}_{α 2} )} ( 2 cos ( {Δϕ}_{α 2} ) ( {E}_{beat} ( {ϕ}_{α 3} ) - {E}_{beat} ( {ϕ}_{α 1} ) ) - ( sin ( {Δϕ}_{α 1} ) + sin ( {Δϕ}_{α 3} ) ) ( {E}_{beat} ( 0 ) - {E}_{beat} ( {ϕ}_{α 2} ) ) ) , 2 cos ( {Δϕ}_{α 2} ) ( {E}_{beat} ( 0 ) - {E}_{beat} ( {ϕ}_{α 2} ) ) ) - {Δϕ}_{α 2} ) \qquad ( 56 )$$
(in Equations (47), (48), (49), (50), (51), and (56),
aᵢ represent amplitudes, ωᵢ represent angular frequencies, φᵢ represent phases, t represents a time, and ω₂−ω₁=ω₃−ω₂=Δω is established,
α₁ᵢ are phase offsets of the second 3-tone signal, and φ_{α1}=α₁₃−2α₁₂+α₁₁ is established when a second-order difference of α₁ᵢ is represented by φ_{α1},
α₂ᵢ are phase offsets of the third 3-tone signal, and φ_{α2}=α₂₃−2α₂₂+α₂₁ is established when a second-order difference of α₂ᵢ is represented by φ_{α2},
α₃ᵢ are phase offsets of the fourth 3-tone signal, and φ_{α3}=α₃₃−2α₃₂+α₃₁ is established when a second-order difference of α₃ᵢ is represented by φ_{α3},
φ_{α1}=π/2+Δφ_{α1}+Δφ_{α2}, φ_{α2}=π+2φ_{α2}, and φ_{α3=3}π/2+Δφ_{α3}+Δφ_{α2} are established,
E_{beat}(0) represents a value that is obtained from a voltage value measured in the voltage measurement step and that is proportional to power of the signal obtained in the first detection step in a case where the first 3-tone signal is detected in the first detection step,
E_{beat}(φ_{α1}) represents a value that is obtained from a voltage value measured in the voltage measurement step and that is proportional to power of the signal obtained in the first detection step in a case where the second 3-tone signal in which the second-order difference of α₁ᵢ is set to φ_{α1} is detected in the first detection step,
E_{beat}(φ_{α2}) represents a value that is obtained from a voltage value measured in the voltage measurement step and that is proportional to power of the signal obtained in the first detection step in a case where the third 3-tone signal in which the second-order difference of α₂ᵢ is set to φ_{α2} is detected in the first detection step, and
E_{beat}(φ_{α3}) represents a value that is obtained from a voltage value measured in the voltage measurement step and that is proportional to power of the signal obtained in the first detection step in a case where the fourth 3-tone signal in which the second-order difference of α₃ᵢ is set to φ_{α3} is detected in the first detection step).

11. A phase characteristic measurement method comprising:
a signal for phase measurements generation step of generating, as a signal for phase measurements, a first 2-tone signal obtained by combining two waves e₁ and e₂ represented by Equation (57), a second 2-tone signal obtained by combining two waves e₂ and e₃ represented by Equation (58), a first 3-tone signal obtained by combining three waves e₁, e₂, and e₃ represented by Equation (59), and a second 3-tone signal obtained by combining three waves e₁, e₂, and e₃ represented by Equation (60);
a first detection step of detecting the signal for phase measurements;
a band-pass filter step of, among signals obtained in the first detection step, allowing a frequency component of an angular frequency difference Δω between waves with adjacent frequencies of each of the signals for phase measurements to pass and blocking a frequency component twice the angular frequency difference Δω and a direct current component;
a second detection step of detecting a signal that has passed in the band-pass filter step;
a voltage measurement step of measuring a voltage of a signal obtained in the second detection step; and
a phase calculation step of calculating a phase φ₂″ represented by Equation (61) or Equation (66),
$$[ Equation 57 ]$$
$${e}_{i} = {a}_{i} cos ( {ω}_{i} t + {ϕ}_{i} + {γ}_{i} ) , i = 1 , 2 \qquad ( 57 )$$
$$[ Equation 58 ]$$
$${e}_{i} = {a}_{i} cos ( {ω}_{i} t + {ϕ}_{i} + {γ}_{i} ) , i = 2 , 3 \qquad ( 58 )$$
$$[ Equation 59 ]$$
$${e}_{i} = {a}_{i} cos ( {ω}_{i} t + {ϕ}_{i} ) , i = 1 , 2 , 3 \qquad ( 59 )$$
$$[ Equation 60 ]$$
$${e}_{i} = {a}_{i} cos ( {ω}_{i} t + {ϕ}_{i} + {α}_{1 i} ) , i = 1 , 2 , 3 \qquad ( 60 )$$
$$[ Equation 61 ]$$
$${ϕ}_{2}^{′′} = \frac{1}{{Δω}^{2}} {tan}^{- 1} ( \frac{1}{cos ( {Δϕ}_{α 1} )} ( - \frac{{E}_{beat} ( {ϕ}_{α 1} ) - {E}_{beat} ( {a}_{3} = 0 ) - {E}_{beat} ( {a}_{1} = 0 )}{{E}_{beat} ( 0 ) - {E}_{beat} ( {a}_{3} = 0 ) - {E}_{beat} ( {a}_{2} = 0 )} - sin ( {Δϕ}_{α 1} ) ) ) \qquad ( 61 )$$
$$[ Equation 66 ]$$
$${ϕ}_{2}^{′′} = \frac{1}{{Δω}^{2}} atan 2 ( \frac{1}{cos ( {Δϕ}_{α 1} )} ( - {E}_{beat} ( {ϕ}_{α 1} ) + {E}_{beat} ( {a}_{3} = 0 ) + {E}_{beat} ( {a}_{1} = 0 ) - sin ( {Δϕ}_{α 2} ) ( {E}_{beat} ( 0 ) - {E}_{beat} ( {a}_{3} = 0 ) - {E}_{beat} ( {a}_{1} = 0 ) - {E}_{beat} ( {a}_{1} = 0 ) ) ) , {E}_{beat} ( 0 ) - {E}_{beat} ( {a}_{3} = 0 ) - {E}_{beat} ( {a}_{1} = 0 ) ) \qquad ( 66 )$$
(in Equations (57), (58), (59), (60), (61), and (66),
aᵢ represent amplitudes, ωᵢ represent angular frequencies, φᵢ represent phases, γᵢ represent arbitrary phases, t represents a time, and ω₂−ω₁=ω₃−ω₂=Δω is established,
α₁ᵢ are phase offsets of the second 3-tone signal, and φ_{α1}=α₁₃−2α₁₂+α₁₁ is established when a second-order difference of α₁ᵢ is represented by φ_{α1},
φ_{α1}=π/2+Δφ_{α1} is established,
E_{beat}(φ_{α1}) represents a value that is obtained from a voltage value measured in the voltage measurement step and that is proportional to power of the signal that has passed in the band-pass filter step in a case where the second 3-tone signal in which the second-order difference of α₁ᵢ is set to φ_{α1} is detected in the first detection step,
E_{beat}(0) represents a value that is obtained from a voltage value measured in the voltage measurement step and that is proportional to power of the signal that has passed in the band-pass filter step in a case where the first 3-tone signal is detected in the first detection step,
E_{beat}(a₁=0) represents a value that is obtained from a voltage value measured in the voltage measurement step and that is proportional to power of the signal that has passed in the band-pass filter step in a case where the second 2-tone signal is detected in the first detection step, and
E_{beat}(a₃=0) represents a value that is obtained from a voltage value measured in the voltage measurement step and that is proportional to power of the signal that has passed in the band-pass filter step in a case where the first 2-tone signal is detected in the first detection step).

12. A phase characteristic measurement method comprising:
a signal for phase measurements generation step of generating, as a signal for phase measurements, a first 2-tone signal obtained by combining two waves e₁ and e₂ represented by Equation (67), a second 2-tone signal obtained by combining two waves e₂ and e₃ represented by Equation (68), and a 3-tone signal obtained by combining three waves e₁, e₂, and e₃ represented by Equation (69);
a first detection step of detecting the signal for phase measurements;
a band-pass filter step of, among signals obtained in the first detection step, allowing a frequency component of an angular frequency difference Δω between waves with adjacent frequencies of each of the signals for phase measurements to pass and blocking a frequency component twice the angular frequency difference Δω and a direct current component;
a second detection step of detecting a signal that has passed in the band-pass filter step;
a voltage measurement step of measuring a voltage of a signal obtained in the second detection step; and
a phase calculation step of calculating a phase φ₂″ represented by Equation (70),
$$[ Equation 67 ]$$
$${e}_{i} = {a}_{i} cos ( {ω}_{i} t + {ϕ}_{i} + {γ}_{i} ) , i = 1 , 2 \qquad ( 67 )$$
$$[ Equation 68 ]$$
$${e}_{i} = {a}_{i} cos ( {ω}_{i} t + {ϕ}_{i} + {γ}_{i} ) , i = 2 , 3 \qquad ( 68 )$$
$$[ Equation 69 ]$$
$${e}_{i} = {a}_{i} cos ( {ω}_{i} t + {ϕ}_{i} ) , i = 1 , 2 , 3 \qquad ( 69 )$$
$$[ Equation 70 ]$$
$${ϕ}_{2}^{′} = \frac{1}{{Δω}^{2}} {cos}^{- 1} ( \frac{{E}_{beat} ( 0 ) - {E}_{beat} ( {a}_{3} = 0 ) - {E}_{beat} ( {a}_{1} = 0 )}{2 \sqrt{{E}_{beat} ( {a}_{1} = 0 ) {E}_{beat} ( {a}_{3} = 0 )}} ) \qquad ( 70 )$$
(in Equations (67), (68), (69), and (70),
aᵢ represent amplitudes, ωᵢ represent angular frequencies, φᵢ represent phases, γᵢ represent arbitrary phases, t represents a time, and ω₂−ω₁=ω₃−ω₂=Δω is established,
E_{beat}(0) represents a value that is obtained from a voltage value measured in the voltage measurement step and that is proportional to power of the signal that has passed in the band-pass filter step in a case where the 3-tone signal is detected in the first detection step,
E_{beat}(a₁=0) represents a value that is obtained from a voltage value measured in the voltage measurement step and that is proportional to power of the signal that has passed in the band-pass filter step in a case where the second 2-tone signal is detected in the first detection step, and
E_{beat}(a₃=0) represents a value that is obtained from a voltage value measured in the voltage measurement step and that is proportional to power of the signal that has passed in the band-pass filter step in a case where the first 2-tone signal is detected in the first detection step).

13. A signal generation method comprising:
the phase characteristic measurement method according to claim 8, in which the signal for phase measurements is generated by a high-frequency signal generation unit in the signal for phase measurements generation step, and the phase φ₂″ is measured from the signal for phase measurements generated in the signal for phase measurements generation step to measure a phase characteristic of the high-frequency signal generation unit; and
a high-frequency signal generation step of generating a high-frequency signal by the high-frequency signal generation unit and outputting the high-frequency signal as an output signal,
wherein a phase characteristic of the high-frequency signal is corrected based on the phase characteristic of the high-frequency signal generation unit measured by the phase characteristic measurement method.

14. A signal analysis method comprising:
the phase characteristic measurement method according to claim 8, in which the signal for phase measurements is generated by a reference signal generation unit in the signal for phase measurements generation step, and the phase φ₂″ is measured from the signal for phase measurements generated in the signal for phase measurements generation step to measure a phase characteristic of the reference signal generation unit;
a reference signal generation step of generating a reference signal by the reference signal generation unit;
a reference signal analysis step of measuring a phase characteristic of the reference signal by a high-frequency signal analysis unit; and
a high-frequency signal analysis step of analyzing an input signal by the high-frequency signal analysis unit,
wherein a phase characteristic of the high-frequency signal analysis unit is calculated from the phase characteristic of the reference signal generation unit measured by the phase characteristic measurement method, and the phase characteristic of the reference signal measured in the reference signal analysis step, a phase characteristic in a case where analysis of the input signal is performed in the high-frequency signal analysis step is corrected based on the calculated phase characteristic of the high-frequency signal analysis unit, and signal analysis of the input signal is performed with the corrected phase characteristic.
